(19) United States
(12) Patent Application Publication
(10) Pub. No.: US 2026/0122866 A1
(43) Pub. Date: Apr. 30, 2026

(54) Liquid-Cooled Power Conversion System for High Power Applications

(71) Applicant: AA Power Inc., Boston, MA (US)

(72) Inventor: Qun Lu, Lexington, MA (US)

(21) Appl. No.: 19/365,159

(22) Filed: Oct. 21, 2025

Related U.S. Application Data
(60) Provisional application No. 63/711,681, filed on Oct. 24, 2024.

(51) Int. Cl. H05K 7/20; H05K 7/14

(52) U.S. Cl. CPC H05K 7/20927; H05K 7/14324

(57) ABSTRACT

A system includes a plurality of power conversion units connected in series between a power source and an output voltage bus, and a housing comprising a first sidewall portion, a second sidewall portion, a bottom case portion and a top case portion, wherein the plurality of power conversion units is placed inside the housing and at least one of the first sidewall portion, the second sidewall portion, the bottom case portion and the top case portion comprises a channel through which coolant flows to cool heat-generating components of the plurality of power conversion units.

### PRIORITY

This application claims the benefit of U.S. Provisional Application No. 63/711,681, filed on Oct. 24, 2024, entitled “Liquid-Cooled Power Conversion System for High Power Applications,” which application is hereby incorporated herein by reference.

### TECHNICAL FIELD

The present invention relates to a power conversion system, and in particular to a liquid-cooled power conversion system for high power applications.

### BACKGROUND

As technologies further advance, a modern data center is equipped with numerous high-performance processors such as graphics processing units (GPUs). The processors are designed to handle intensive computing workloads such as artificial intelligence (AI) training, machine learning, and complex simulations. These GPUs, often organized into high-density racks, deliver exceptional parallel processing power, enabling the rapid analysis and processing of vast amounts of data.

In a data center, a processor is powered by a power conversion system. This power conversion system is connected between the electric grid and the processor. The power conversion system is configured to convert the ac voltage of the electric grid into a voltage suitable for driving the processor. In operation, the power conversion system produces excess heat, which is commonly released into the surrounding atmosphere for dissipation. Heat dissipation occurs until a component reaches thermal equilibrium. In other words, its temperature stabilizes. At this equilibrium temperature, the rate of heat dissipation matches the rate of heat production, resulting in a constant temperature. Therefore, the temperature remains unchanged over time. In some operating conditions, the heat generated by the power conversion system cannot be fully dissipated. The extra heat causes a high operating temperature. The excessively high operating temperature has a tendency to degrade components and reduce the lifespan of the power conversion system. A recognized solution for operation in the high temperature involves cooling the power conversion system using a liquid, which lowers its temperature to achieve thermal equilibrium.

A liquid cooled power conversion system is employed to provide power for a high-performance and densely packed data center. In operation, the power conversion system generates heat. The heat is generated primarily from electrical components such as transformers, inductors, capacitors, and power switches. This heat needs to be efficiently removed to prevent overheating. A liquid cooled plate is designed to be in direct contact with the power supply. The plate is typically made of thermally conductive materials such as copper, aluminum and the like. The thermally conductive materials can efficiently transfer heat from the power supply to the liquid cooled plate. Inside the liquid cooled plate, there are channels through which a coolant (e.g., water) circulates. As the heat is transferred from the power supply to the liquid cooled plate, the coolant absorbs this heat. The heated coolant is then circulated out of the liquid cooled plate and into the broader liquid cooling loop of the rack. This loop may include a heat exchanger dissipating the heat from the coolant to the outside environment. The cooled liquid then returns to the liquid cooled plate to absorb more heat. The cooling process forms a continuous cooling cycle. This cooling process keeps the power conversion system at a safe operating temperature under various operating conditions.

In operation, when the liquid cooled plate is not in close or direct contact with the power conversion system, the efficiency of heat transfer is significantly compromised. For example, if there is a gap or poor contact between the liquid cooled plate and the power conversion system, the heat generated by the power conversion system cannot be effectively transferred to the liquid cooled plate. This results in higher thermal resistance. The higher thermal resistance prevents the heat in the power conversion system from being dissipated by the circulating coolant. Consequently, the power conversion system may operate at higher temperatures, leading to reduced performance, potential overheating, and decreased reliability over time. It is desirable to have an efficient cooling apparatus to mitigate this issue. The present disclosure addresses this need.

### SUMMARY

These and other problems are generally solved or circumvented, and technical advantages are generally achieved, by preferred embodiments of the present disclosure which provide a liquid cooled power conversion system for high power applications.

In accordance with an embodiment, a system comprises a plurality of power conversion units connected in series between a power source and an output voltage bus, and a housing comprising a first sidewall portion, a second sidewall portion, a bottom case portion and a top case portion, wherein the plurality of power conversion units is placed inside the housing and at least one of the first sidewall portion, the second sidewall portion, the bottom case portion and the top case portion comprises a channel through which coolant flows to cool heat-generating components of the plurality of power conversion units.

In accordance with another embodiment, a power supply unit comprises a printed circuit board on which one or more magnetic components are mounted, a cold plate radiator having at least one liquid channel, the cold plate radiator including a liquid inlet and a liquid outlet configured to allow coolant circulation, a thermally conductive adhesive disposed between the magnetic components and the cold plate radiator, and a plurality of power switches thermally coupled to sidewalls of the cold plate radiator, wherein the coolant flowing through the liquid channel absorbs heat generated by the magnetic components and the power switches.

In accordance with yet another embodiment, a liquid-cooled power supply unit comprises a case having a wall, a liquid pipe disposed inside the case and arranged along the wall or in thermal contact with a radiator, and a plurality of heat-generating components thermally coupled to the liquid pipe through the wall or through at least one radiator, wherein a coolant flows through the liquid pipe to remove heat from the plurality of heat-generating components.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a perspective view of the power supply unit in accordance with various embodiments of the present disclosure;

FIG. 2 illustrates a top view and a side view of the power supply unit shown in FIG. 1 in accordance with various embodiments of the present disclosure;

FIG. 3 illustrates another perspective view of the power supply unit in accordance with various embodiments of the present disclosure;

FIG. 4 illustrates an exploded view of the interior of the power supply unit shown in FIG. 3 in accordance with various embodiments of the present disclosure;

FIG. 5 illustrates a sectional view along a plane that is parallel to the housing floor and that bisects the housing inlet and the housing outlet;

FIG. 6 illustrates a cut-away view of the left cold plate in accordance with various embodiments of the present disclosure;

FIG. 7 illustrates a cut-away view of the right cold plate in accordance with various embodiments of the present disclosure;

FIG. 8 illustrates a perspective view of the cold plates in accordance with various embodiments of the present disclosure;

FIG. 9 illustrates an implementation of the left cold plate in accordance with various embodiments of the present disclosure;

FIG. 10 illustrates an implementation of the right cold plate in accordance with various embodiments of the present disclosure;

FIG. 11 illustrates a connecting channel placed between the left cold plate and the right cold plate in accordance with various embodiments of the present disclosure;

FIG. 12 illustrates an integrated tube in accordance with various embodiments of the present disclosure;

FIG. 13 illustrates a top case portion of the housing in accordance with various embodiments of the present disclosure;

FIG. 14 illustrates a bottom case portion of the housing in accordance with various embodiments of the present disclosure;

FIG. 15 illustrates a first cooling implementation of the housing in accordance with various embodiments of the present disclosure;

FIG. 16 illustrates a second cooling implementation of the housing in accordance with various embodiments of the present disclosure;

FIG. 17 illustrates a third cooling implementation of the housing in accordance with various embodiments of the present disclosure;

FIG. 18 illustrates a fourth cooling implementation of the housing in accordance with various embodiments of the present disclosure;

FIG. 19 illustrates a fifth cooling implementation of the housing in accordance with various embodiments of the present disclosure;

FIG. 20 illustrates a sixth cooling implementation of the housing in accordance with various embodiments of the present disclosure;

FIG. 21 illustrates a seventh cooling implementation of the housing in accordance with various embodiments of the present disclosure;

FIG. 22 illustrates an eighth cooling implementation of the housing in accordance with various embodiments of the present disclosure;

FIG. 23 illustrates a first implementation of the sidewall portion in accordance with various embodiments of the present disclosure;

FIG. 24 illustrates a second implementation of the sidewall portion in accordance with various embodiments of the present disclosure;

FIG. 25 illustrates a third implementation of the sidewall portion in accordance with various embodiments of the present disclosure;

FIG. 26 illustrates an exploded view of the power supply unit comprising a cold plate radiator in accordance with various embodiments of the present disclosure;

FIG. 27 illustrates a top view and side views of the power supply unit comprising a cold plate radiator in accordance with various embodiments of the present disclosure;

FIG. 28 illustrates a sectional view along a plane that is parallel to the housing floor and that bisects the housing inlet and the housing outlet;

FIG. 29 illustrates a detailed drawing of the cold plate radiator in accordance with various embodiments of the present disclosure;

FIG. 30 illustrates a cold plate radiator having a plurality of sub-divisions in accordance with various embodiments of the present disclosure;

FIG. 31 illustrates a cross-sectional view along line A-A of the first implementation;

FIG. 32 illustrates an exploded view of the liquid-cooled power supply unit and a cross-sectional view along line B-B of the first implementation;

FIG. 33 illustrates a cross-sectional view along line A-A of the second implementation;

FIG. 34 illustrates a perspective view of the liquid pipe and heatsinks and a cross-sectional view along line B-B of the second implementation;

FIG. 35 illustrates a cross-sectional view along line A-A of the third implementation;

FIG. 36 illustrates an exploded view of the third implementation;

FIG. 37 illustrates a cross-sectional view along line A-A of the fourth implementation;

FIG. 38 illustrates an exploded view of the liquid pipe and heat-generating components of the same implementation;

FIG. 39 illustrates a fifth implementation of the liquid-cooled power supply unit in accordance with various embodiments of the present disclosure;

FIG. 40 illustrates a first implementation of a three-layer structure for improving EMI performance in the power supply unit in accordance with various embodiments of the present disclosure;

FIG. 41 illustrates a second implementation of the three-layer structure for improving EMI performance in accordance with various embodiments of the present disclosure;

FIG. 42 illustrates an application of the three-layer structure positioned between a heat-generating component and a heatsink in accordance with various embodiments of the present disclosure;

FIG. 43 illustrates a sixth implementation of the liquid-cooled power supply unit in accordance with various embodiments of the present disclosure;

FIG. 44 illustrates a cross-sectional view along line A-A of the seventh implementation; and

FIG. 45 illustrates an exploded view of the same implementation.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The present disclosure will be described with respect to preferred embodiments in a specific context, namely a liquid cooled power conversion system for high power applications. The disclosure may also be applied, however, to a variety of power conversion systems. Hereinafter, various embodiments will be explained in detail with reference to the accompanying drawings.

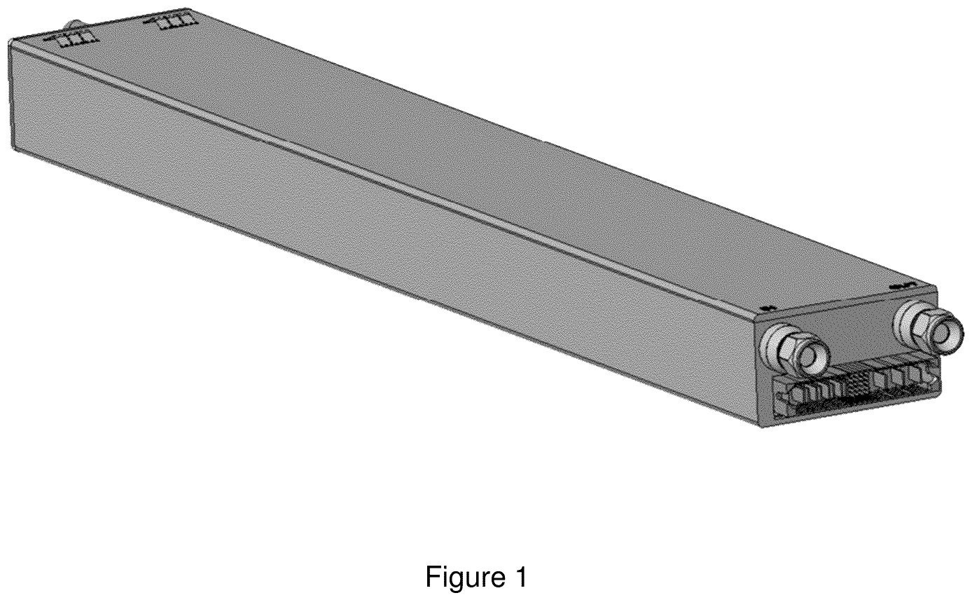

FIG. 1 illustrates a perspective view of a power supply unit in accordance with various embodiments of the present disclosure. The power unit represents a liquid-cooled power conversion system configured for high-power applications. The power unit includes a housing that encloses one or more power conversion modules, such as DC/DC converters, transformers, inductors, capacitors, and switching components that generate significant heat during operation. The housing is generally formed of thermally conductive materials to facilitate efficient heat dissipation and may integrate fluid channels or cold-plate structures for liquid cooling.

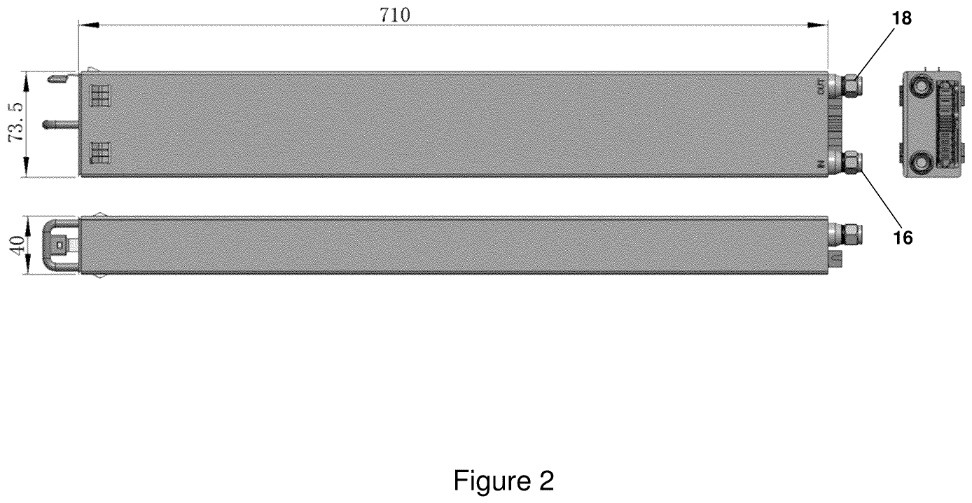

FIG. 2 illustrates a top view and a side view of the power supply unit shown in FIG. 1 in accordance with various embodiments of the present disclosure. As shown in FIG. 2, a coolant inlet 16 and a coolant outlet 18 are arranged at an upper portion of one end of the power supply unit to enable liquid circulation through internal cooling channels adjacent to the heat-generating components. The top and side views further illustrate the compact arrangement of electrical connectors and the structural integration between the cooling system and the housing. This configuration allows uniform heat removal while maintaining mechanical rigidity and minimizing the overall size of the power unit. Throughout the description, the coolant inlet 16 may be alternatively referred to as a liquid inlet, a housing inlet or a first plate inlet. The coolant outlet 18 may be alternatively referred to as a liquid outlet, a housing outlet or a second plate outlet.

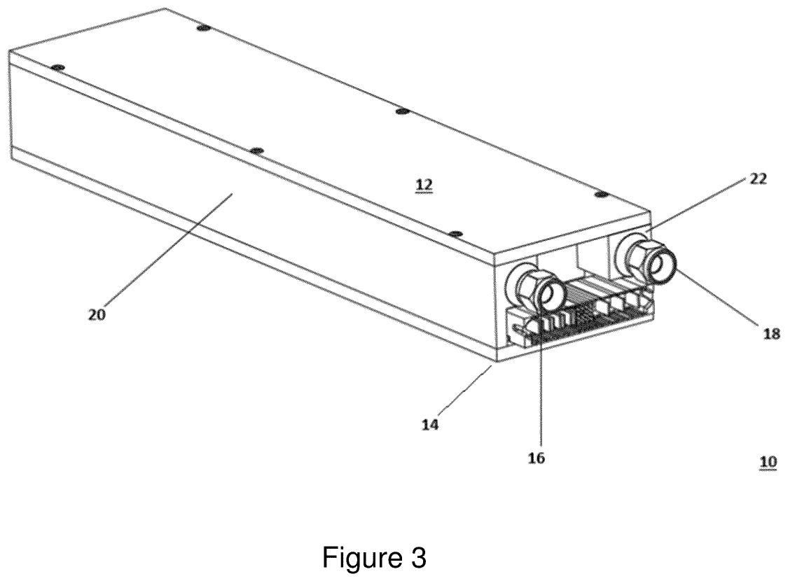

FIG. 3 illustrates another perspective view of the power supply unit in accordance with various embodiments of the present disclosure. The power supply unit may comprise a plurality of power conversion units connected in series between a power source and an output voltage bus. As shown in FIG. 3, the power supply unit 10 includes a housing 12, which has a rear end 14. At this rear end, there is a housing inlet 16 for cooling fluid to enter and a housing outlet 18 for the cooling fluid to exit after absorbing heat generated within the housing. An external pump supplies the energy necessary to drive the fluid flow from the housing inlet 16, through the housing, and out the housing outlet 18. The housing 12 contains two cold plates, a first cold plate 20 and a second cold plate 22, that extend longitudinally from the rear end 14 to the front end. The housing inlet 16 and outlet 18 are connected to the first and second cold plates, respectively, allowing fluid flow between them. Throughout the description, the first cold plate 20 may be alternatively referred to as a left cold plate, a first sidewall or a first sidewall portion. The second cold plate 22 may be alternatively referred to as a right cold plate, a second sidewall or a second sidewall portion. The housing 12 may be alternatively referred to as a case. The power supply unit may be alternatively referred to as a liquid-cooled power supply unit.

The power supply unit 10 handles high levels of electrical current through connectors located at the rear end 14. These electrical connectors contain conductors that carry current, which results in ohmic heating as current flows through them. The heating is influenced by the current density, or the amount of current passing through a given area of the conductor. Since ohmic heating is directly related to current density, larger connectors are beneficial as they reduce current density by distributing the current over a larger surface area. This, in turn, minimizes heating and reduces ohmic losses.

The use of these larger connectors requires significant space at the rear end 14. In traditional air-cooled power supplies, much of this space is occupied by air vents, limiting the size of the connectors. However, since the power supply unit 10 shown in FIG. 3 is liquid-cooled, the need for bulky air vents is eliminated, freeing up space for larger connectors. Additionally, to further optimize space, the housing inlet 16 and outlet 18 are positioned at the corners of the rear end 14, increasing the available contiguous area and allowing for even larger connectors, thereby reducing ohmic heating losses.

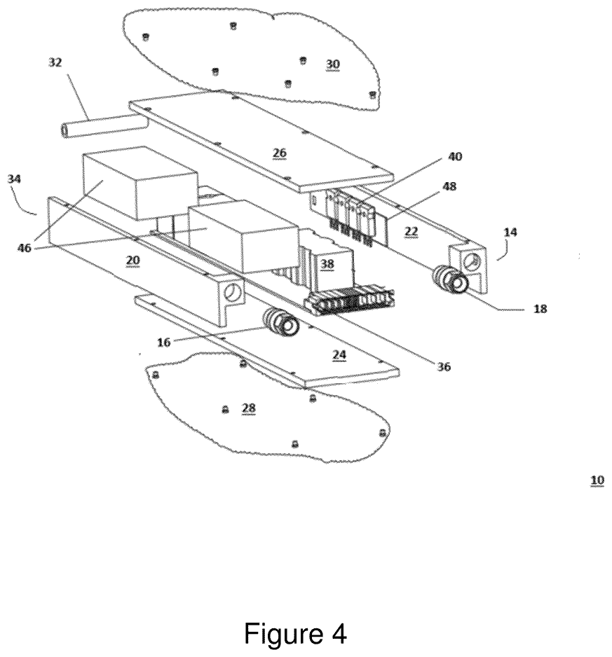

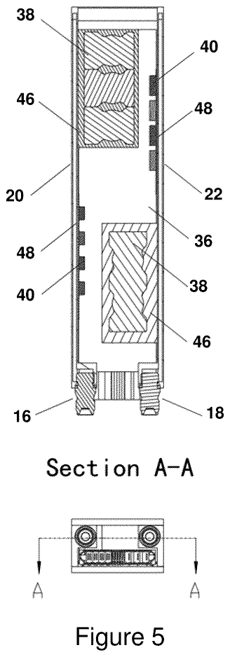

FIG. 4 illustrates an exploded view of the interior of the power supply unit shown in FIG. 3 in accordance with various embodiments of the present disclosure. FIG. 5 illustrates a sectional view along a plane that is parallel to the housing floor and that bisects the housing inlet and the housing outlet. The sectional view is taken along line A-A. As shown in FIG. 4, the first cold plate 20 and the second cold plate 22 are secured to the housing floor 24 and housing ceiling 26 using corresponding floor screws 28 and ceiling screws 30. A connecting channel 32 runs transversely at the front end 34 of the housing 12.

A printed circuit board (PCB) 36 is placed inside the housing 12. The printed circuit board 36 supports various components that require cooling. These components include magnetic components 38, typically inductors, and semiconductor components such as power switches 40. Another component requiring cooling is a heatsink mounted on the printed circuit board 36. These components are thermally connected to either the first cold plate 20 or the second cold plate 22.

In some embodiments, thermal communication between the power supply components and the cold plates 20, 22 is enhanced by thermally-conductive adhesive 46 and thermal interface material pads 48. These materials reduce interfacial thermal resistance and improve heat conduction to the cold plates 20 and 22.

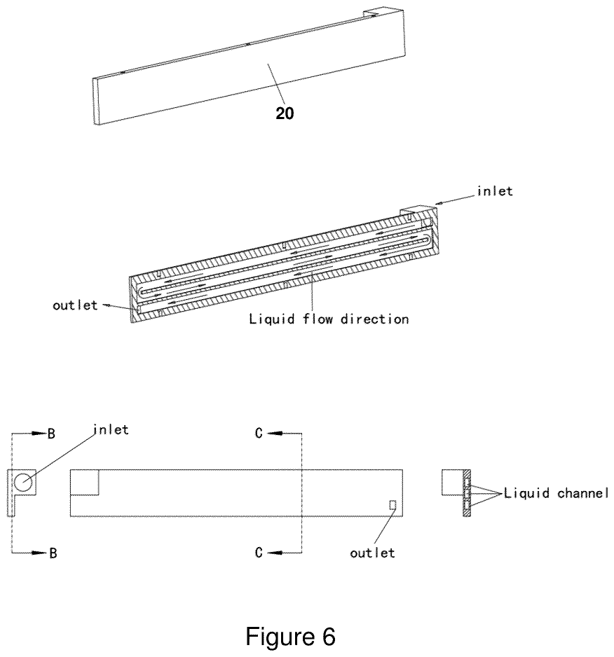

FIG. 6 illustrates a cut-away view of the left cold plate in accordance with various embodiments of the present disclosure. The left cold plate has an interior wall facing the interior of the power supply unit and an exterior wall facing the exterior of the power supply unit. The upper portion of FIG. 6 shows a perspective view of the left cold plate. The middle portion of FIG. 6 shows a cutaway view of the left cold plate taken along line B-B. The cutaway view shows an intramural channel running inside the left cold plate, allowing fluid communication between a first plate inlet and a first plate outlet. The first plate outlet is connected to the right cold plate 22 through the connecting channel 32. In some embodiments, the intramural channel follows a meandering or serpentine path through the left cold plate, causing the coolant to flow in alternating directions within the left cold plate. The bottom right corner of FIG. 6 shows a cross-sectional view of the left cold plate 20 along line C-C.

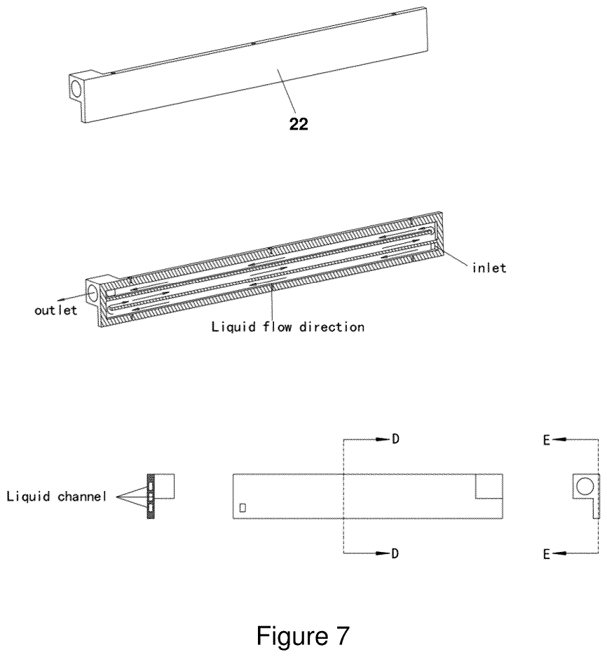

FIG. 7 illustrates a cut-away view of the right cold plate in accordance with various embodiments of the present disclosure. The right cold plate has an interior wall facing the interior of the power supply unit and an exterior wall facing the exterior of the power supply unit. The upper portion of FIG. 7 shows a perspective view of the right cold plate. The middle portion of FIG. 7 shows a cutaway view of the right cold plate along line E-E. The cutaway view shows an intramural channel running inside the right cold plate, allowing fluid communication between a second plate inlet and a second plate outlet. The second plate inlet is connected to the first plate outlet shown in FIG. 6 through the connecting channel 32. In some embodiments, the intramural channel follows a meandering or serpentine path through the right cold plate, causing the coolant to flow in alternating directions within the right cold plate. The bottom left corner of FIG. 7 shows a cross-sectional view of the right cold plate 22 along line D-D.

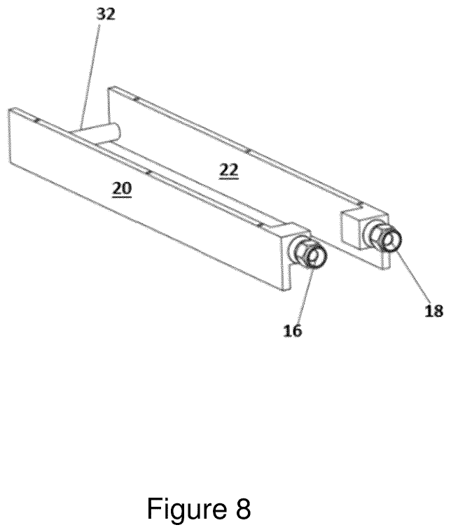

FIG. 8 illustrates a perspective view of the cold plates in accordance with various embodiments of the present disclosure. The first and second cold plates 20, 22 have similar structures. The first and second cold plates 20, 22 are preferably made of a material having high thermal conductivity. Suitable examples include metals, such as aluminum and alloys thereof.

As shown in FIG. 8, the connecting channel 32 connects the first and second cold plates 20 and 22.

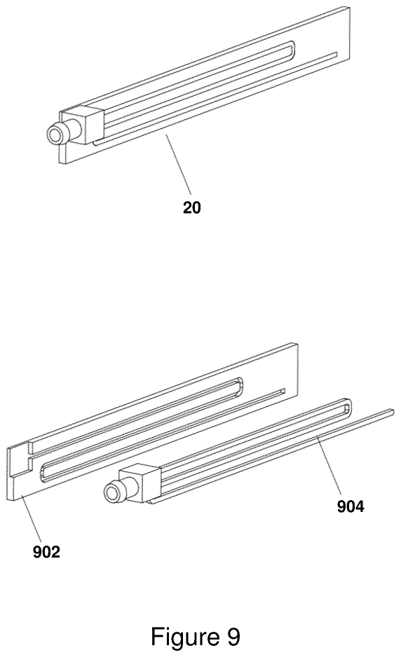

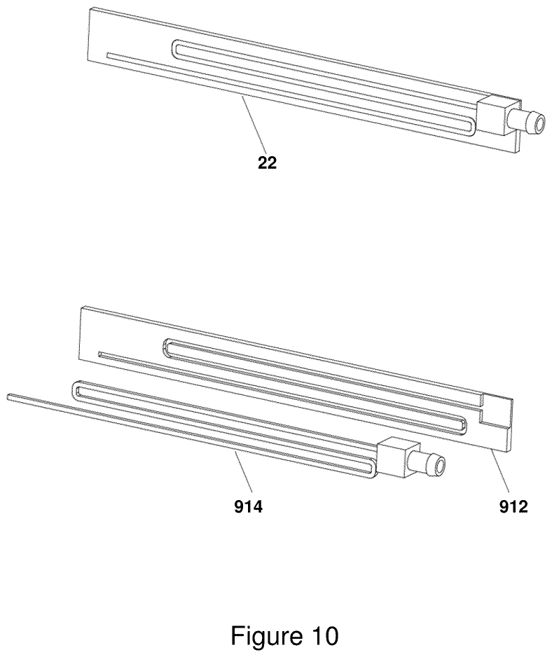

FIG. 9 illustrates an implementation of the left cold plate in accordance with various embodiments of the present disclosure. FIG. 10 illustrates an implementation of the right cold plate in accordance with various embodiments of the present disclosure. The left cold plate 20 comprises a left cold plate substrate 902 and a left copper tube 904. The right cold plate 22 comprises a right cold plate substrate 912 and a right copper tube 914. As shown in FIG. 9, the left cold plate substrate 902 comprises a first meandering trench. The left copper tube 904 is a meandering copper tube embedded in the first meandering trench to form the first meandering channel. As shown in FIG. 10, the right cold plate substrate 912 comprises a second meandering trench. The right copper tube 914 is a meandering copper tube embedded in the second meandering trench to form the second meandering channel. In operation, coolant flows through the first meandering channel and the second meandering channel, and further flows into the outlet after absorbing heat generated by the heat-generating components.

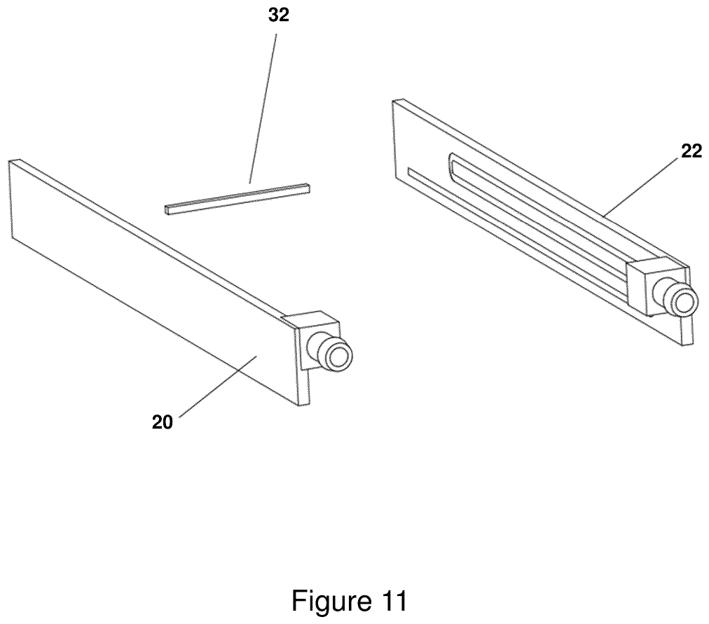

FIG. 11 illustrates a connecting channel placed between the left cold plate and the right cold plate in accordance with various embodiments of the present disclosure. The first sidewall portion comprises a first meandering channel connected to an inlet. The second sidewall portion comprises a second meandering channel connected to an outlet. The connecting channel 32 is connected between the first meandering channel and the second meandering channel. The coolant flows through the first meandering channel, the connecting channel and the second meandering channel and into the outlet to absorb heat generated by the heat-generating components.

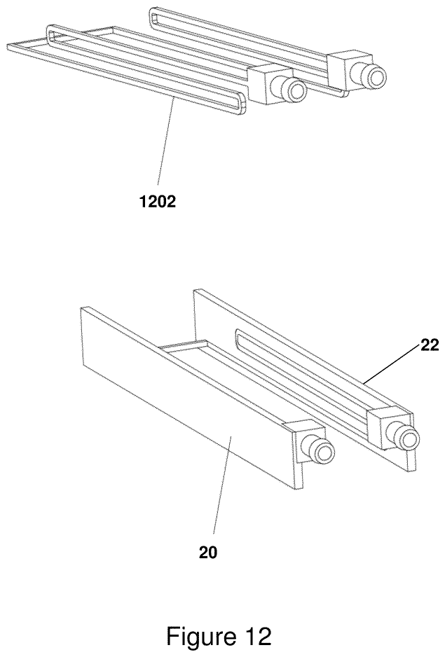

FIG. 12 illustrates an integrated tube in accordance with various embodiments of the present disclosure. As shown in FIG. 12, the first sidewall portion comprises a first meandering trench. The second sidewall portion comprises a second meandering trench. An integrated copper tube 1202 includes a first meandering copper tube portion embedded in the first meandering trench, a second meandering copper tube portion embedded in the second meandering trench and a connecting portion to form a channel to absorb heat generated by the heat-generating components.

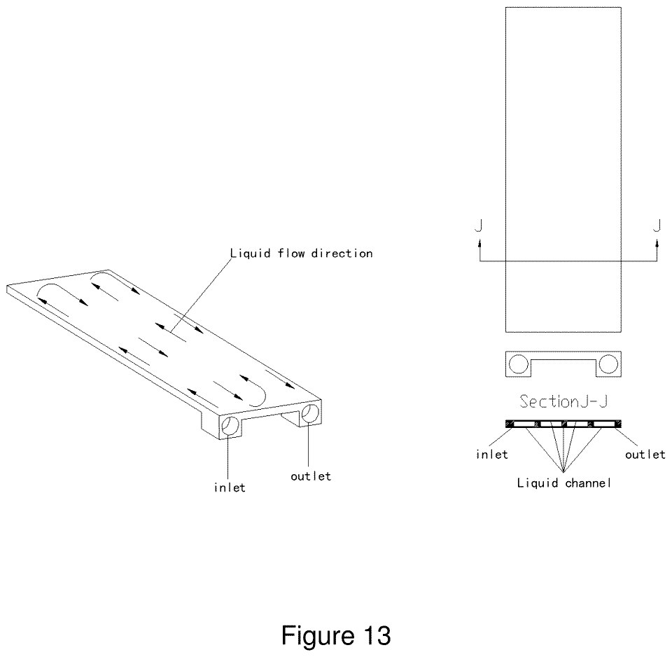

FIG. 13 illustrates a top case portion of the housing in accordance with various embodiments of the present disclosure. The top case portion comprises a meandering channel connected between an inlet and an outlet. As shown in FIG. 13, the inlet is adjacent to a leftmost corner of the top case portion. The outlet is adjacent to a rightmost corner of the top case portion. The right bottom corner of FIG. 13 shows a cross-sectional view of the top case portion along line J-J.

In operation, the coolant flows through the liquid channel from the inlet to the outlet to absorb heat generated by the heat-generating components.

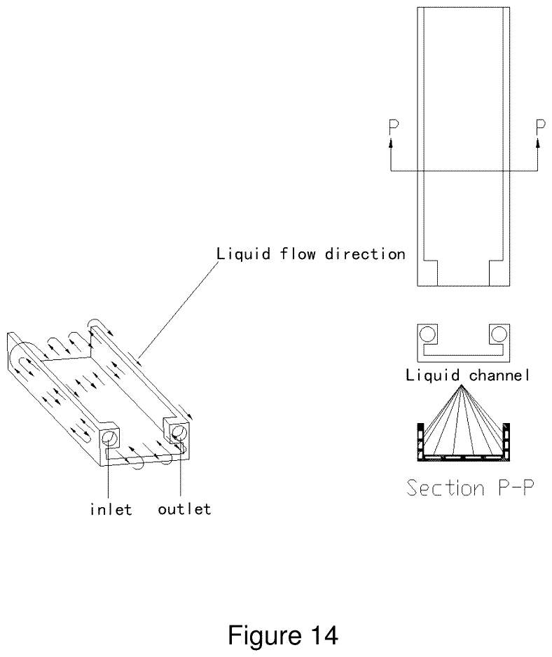

FIG. 14 illustrates a bottom case portion of the housing in accordance with various embodiments of the present disclosure. The bottom case portion comprises a meandering channel connected between an inlet and an outlet. As shown in FIG. 14, the inlet is adjacent to a leftmost corner of the bottom case portion. The outlet is adjacent to a rightmost corner of the bottom case portion. The right bottom corner of FIG. 14 shows a cross-sectional view of the bottom case portion along line P-P.

In operation, the coolant flows through the liquid channel from the inlet to the outlet to absorb heat generated by the heat-generating components.

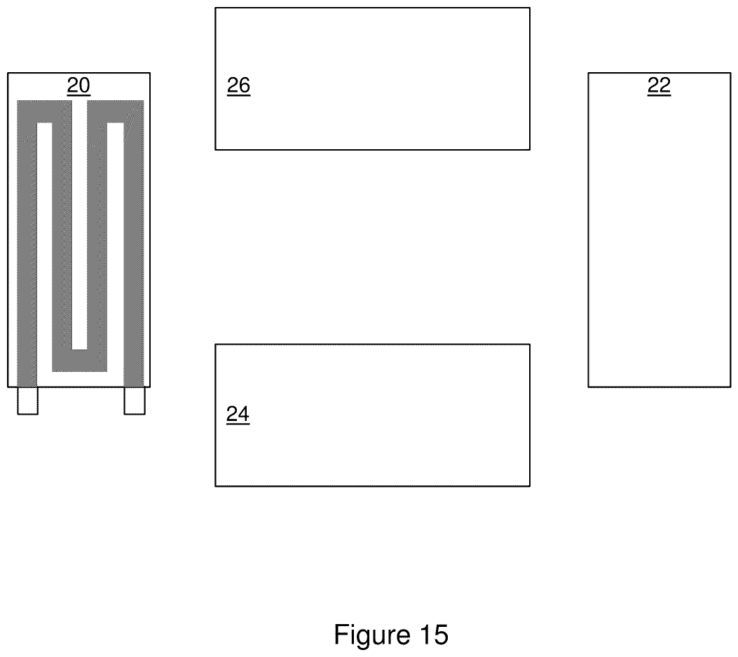

FIGS. 15-25 illustrate various cooling implementations of the housing in accordance with various embodiments of the present disclosure. For clarity in depicting the liquid channels, the first sidewall portion 20, the second sidewall portion 22, the bottom case portion 24 and the top case portion 26 are shown laid out on a common plane. In actual use, these four portions are assembled to form the housing of the power supply unit, as shown in earlier figures (e.g., FIG. 4).

FIG. 15 illustrates a first cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. In operation, the first meandering channel is configured to provide thermal communication with the heat-generating components. More particularly, coolant flowing from the first inlet to the first outlet absorbs heat generated by the heat-generating components.

It should be noted that while FIG. 15 shows the meandering channel is in the first sidewall portion 20, depending on design needs, a similar meandering channel may be formed in the second sidewall portion 22.

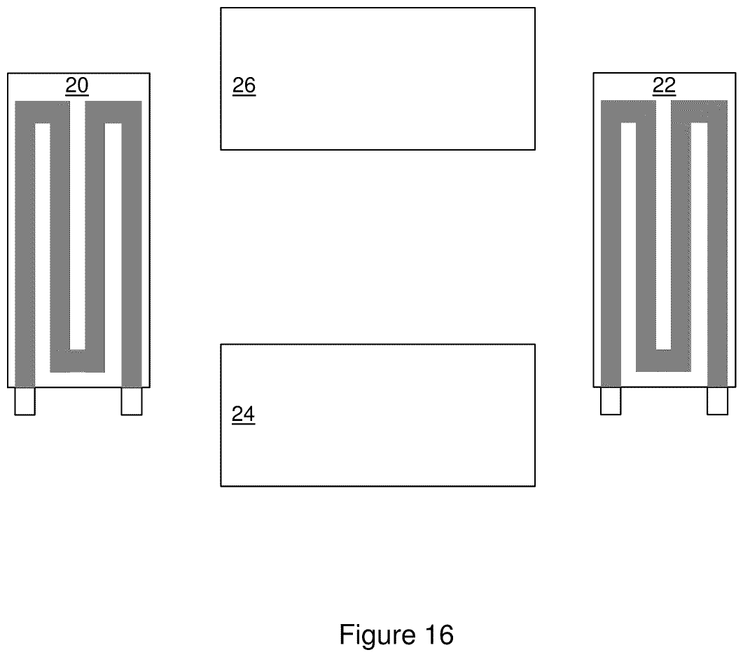

FIG. 16 illustrates a second cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The second sidewall portion 22 comprises a second meandering channel connected between a second inlet and a second outlet. The second inlet is adjacent to a topmost corner of the second sidewall portion. The second outlet is adjacent to a bottommost corner of the second sidewall portion. The first meandering channel and the second meandering channel are configured to provide thermal communication with the heat-generating components.

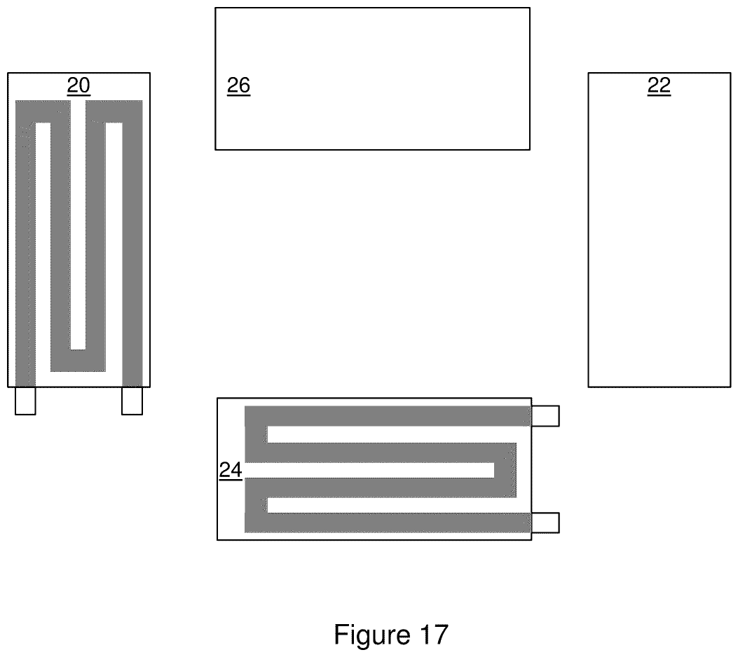

FIG. 17 illustrates a third cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The bottom case portion 24 comprises a third meandering channel connected between a third inlet and a third outlet. The third inlet is adjacent to a leftmost corner of the bottom case portion. The third outlet is adjacent to a rightmost corner of the bottom case portion. The first meandering channel and the third meandering channel are configured to provide thermal communication with the heat-generating components.

It should be noted that, while FIG. 17 illustrates a cooling combination comprising a meandering channel in the first sidewall portion 20 and a meandering channel in the bottom case portion 24, the sidewall meandering channel may, depending on design requirements, instead be formed in the second sidewall portion 22.

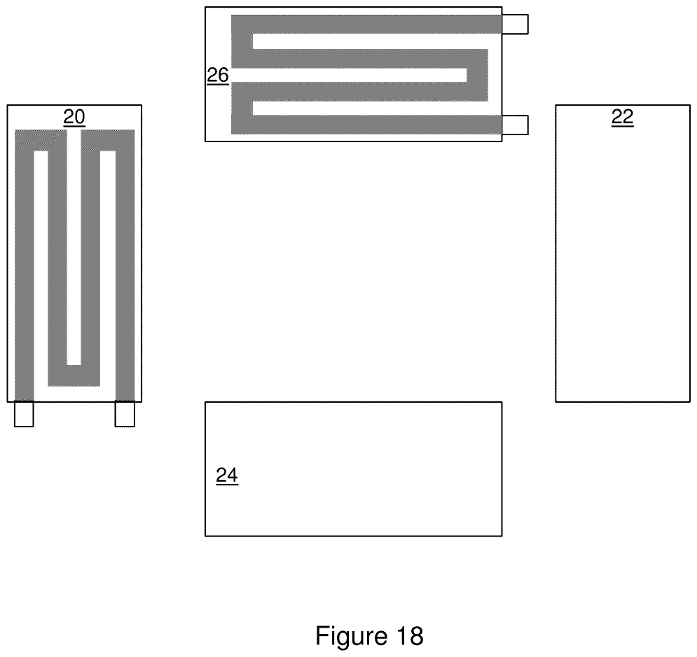

FIG. 18 illustrates a fourth cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The top case portion 26 comprises a fourth meandering channel connected between a fourth inlet and a fourth outlet. The fourth inlet is adjacent to a leftmost corner of the top case portion. The fourth outlet is adjacent to a rightmost corner of the top case portion. The first meandering channel and the fourth meandering channel are configured to provide thermal communication with the heat-generating components.

It should be noted that, while FIG. 18 illustrates a cooling combination comprising a meandering channel in the first sidewall portion 20 and a meandering channel in the top case portion 26, the sidewall meandering channel may, depending on design requirements, instead be formed in the second sidewall portion 22.

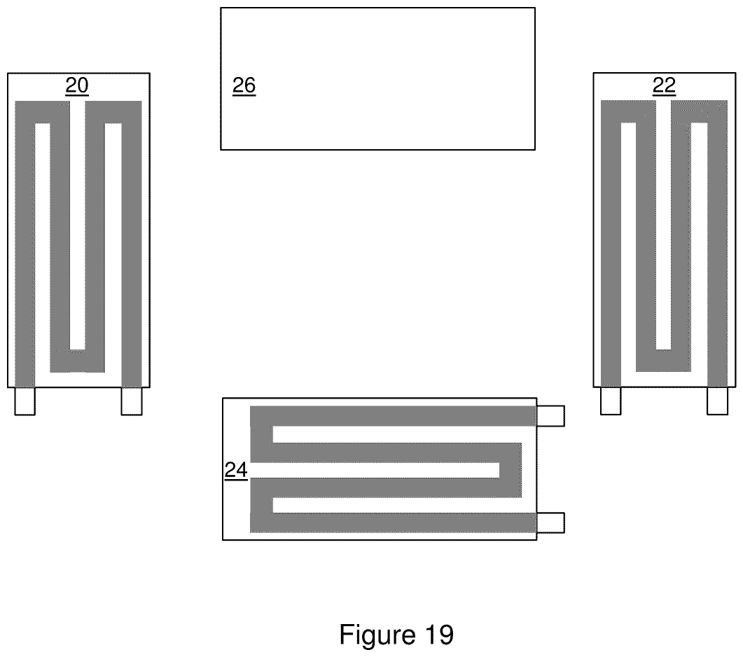

FIG. 19 illustrates a fifth cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The second sidewall portion 22 comprises a second meandering channel connected between a second inlet and a second outlet. The second inlet is adjacent to a topmost corner of the second sidewall portion. The second outlet is adjacent to a bottommost corner of the second sidewall portion. The bottom case portion 24 comprises a third meandering channel connected between a third inlet and a third outlet. The third inlet is adjacent to a leftmost corner of the bottom case portion. The third outlet is adjacent to a rightmost corner of the bottom case portion. The first meandering channel, the second meandering channel and the third meandering channel are configured to provide thermal communication with the heat-generating components.

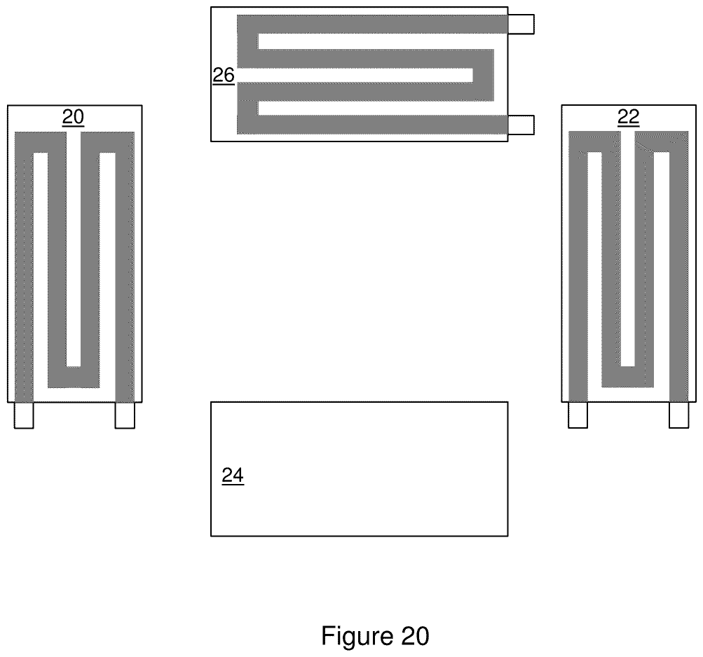

FIG. 20 illustrates a sixth cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The second sidewall portion 22 comprises a second meandering channel connected between a second inlet and a second outlet. The second inlet is adjacent to a topmost corner of the second sidewall portion. The second outlet is adjacent to a bottommost corner of the second sidewall portion. The top case portion 26 comprises a fourth meandering channel connected between a fourth inlet and a fourth outlet. The fourth inlet is adjacent to a leftmost corner of the top case portion. The fourth outlet is adjacent to a rightmost corner of the top case portion. The first meandering channel, the second meandering channel and the fourth meandering channel are configured to provide thermal communication with the heat-generating components.

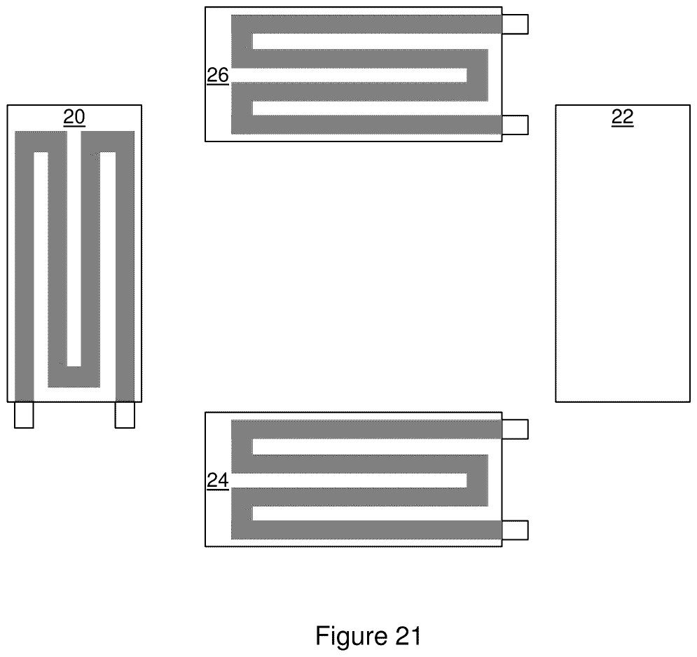

FIG. 21 illustrates a seventh cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The bottom case portion 24 comprises a third meandering channel connected between a third inlet and a third outlet. The third inlet is adjacent to a leftmost corner of the bottom case portion. The third outlet is adjacent to a rightmost corner of the bottom case portion. The top case portion 26 comprises a fourth meandering channel connected between a fourth inlet and a fourth outlet. The fourth inlet is adjacent to a leftmost corner of the top case portion. The fourth outlet is adjacent to a rightmost corner of the top case portion. The first meandering channel, the third meandering channel and the fourth meandering channel are configured to provide thermal communication with the heat-generating components.

It should be noted that, while FIG. 21 illustrates a cooling combination comprising a meandering channel in the first sidewall portion 20 and meandering channels in the bottom and top case portions, the sidewall meandering channel may, depending on design requirements, instead be formed in the second sidewall portion 22.

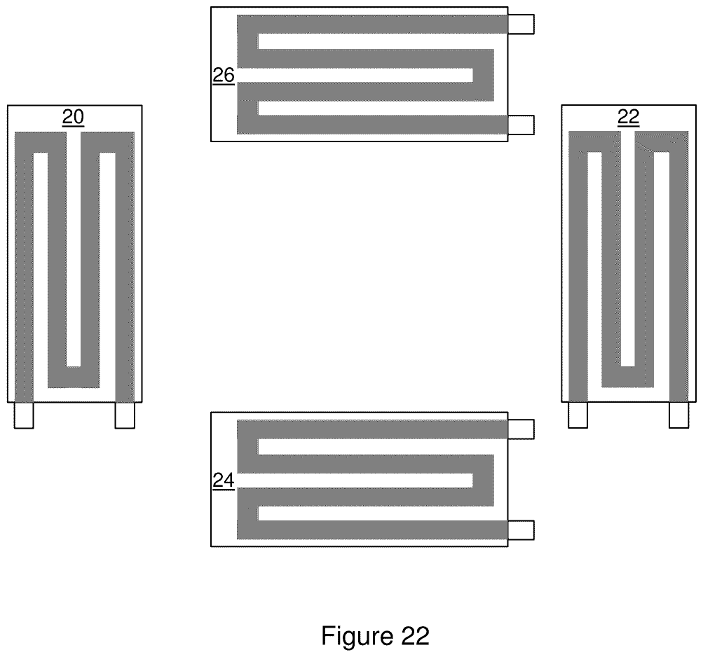

FIG. 22 illustrates an eighth cooling implementation of the housing in accordance with various embodiments of the present disclosure. The first sidewall portion 20 comprises a first meandering channel connected between a first inlet and a first outlet. The first inlet is adjacent to a topmost corner of the first sidewall portion. The first outlet is adjacent to a bottommost corner of the first sidewall portion. The second sidewall portion 22 comprises a second meandering channel connected between a second inlet and a second outlet. The second inlet is adjacent to a topmost corner of the second sidewall portion. The second outlet is adjacent to a bottommost corner of the second sidewall portion. The bottom case portion 24 comprises a third meandering channel connected between a third inlet and a third outlet. The third inlet is adjacent to a leftmost corner of the bottom case portion. The third outlet is adjacent to a rightmost corner of the bottom case portion. The top case portion 26 comprises a fourth meandering channel connected between a fourth inlet and a fourth outlet. The fourth inlet is adjacent to a leftmost corner of the top case portion. The fourth outlet is adjacent to a rightmost corner of the top case portion. The first meandering channel, the second meandering channel, the third meandering channel and the fourth meandering channel are configured to provide thermal communication with the heat-generating components.

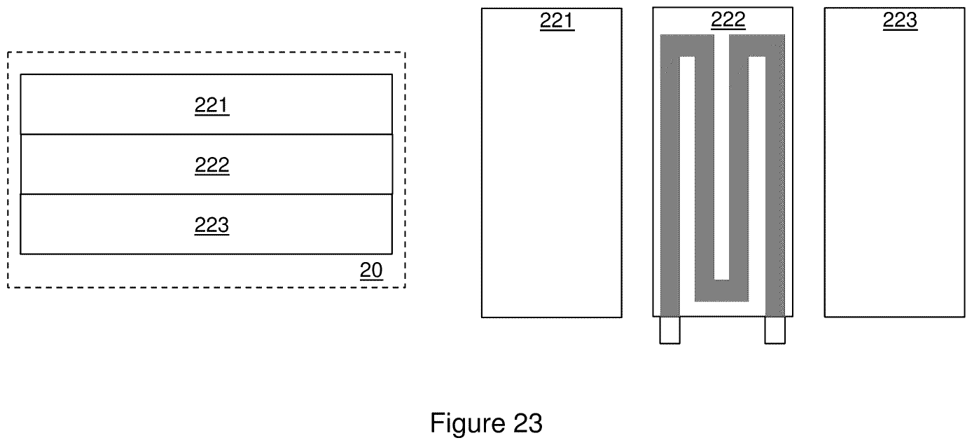

FIG. 23 illustrates a first implementation of the sidewall portion in accordance with various embodiments of the present disclosure. The first sidewall portion 20 is used as an example to illustrate the first implementation. As shown in FIG. 23, the first sidewall portion 20 comprises a first layer 221, a second layer 222 and a third layer 223. As shown in FIG. 23, the first layer 221 is in direct contact with the second layer 222, and the second layer 222 is in direct contact with the third layer 223. The first layer is formed of aluminum and functions as an interior sidewall. The second layer is formed of copper and comprises a meandering channel extending between an inlet and an outlet. The meandering channel is configured to provide thermal communication with the heat-generating components. The third layer is formed of aluminum and functions as an exterior sidewall.

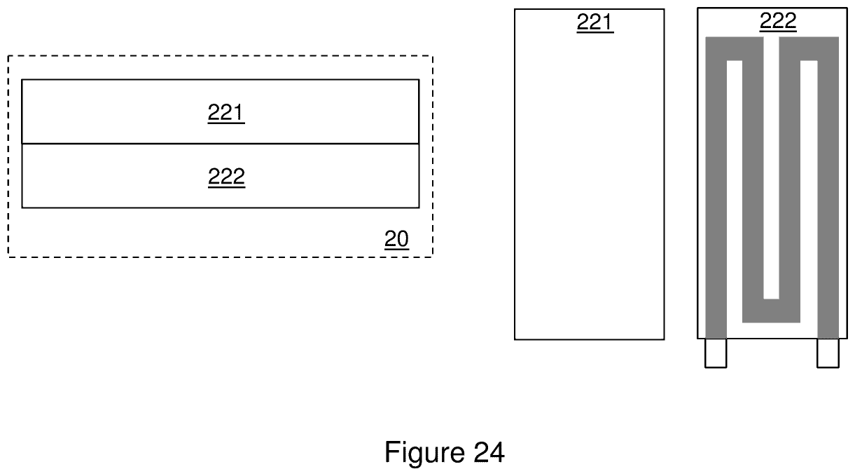

FIG. 24 illustrates a second implementation of the sidewall portion in accordance with various embodiments of the present disclosure. The first sidewall portion 20 is used as an example to illustrate the second implementation. As shown in FIG. 24, the first sidewall portion 20 comprises a first layer 221 and a second layer 222. As shown in FIG. 24, the first layer 221 is in direct contact with the second layer 222. The first layer is formed of aluminum and functions as an interior sidewall. The second layer is formed of copper and functions as an exterior sidewall. The second layer comprises a meandering channel extending between an inlet and an outlet. The meandering channel is configured to provide thermal communication with the heat-generating components.

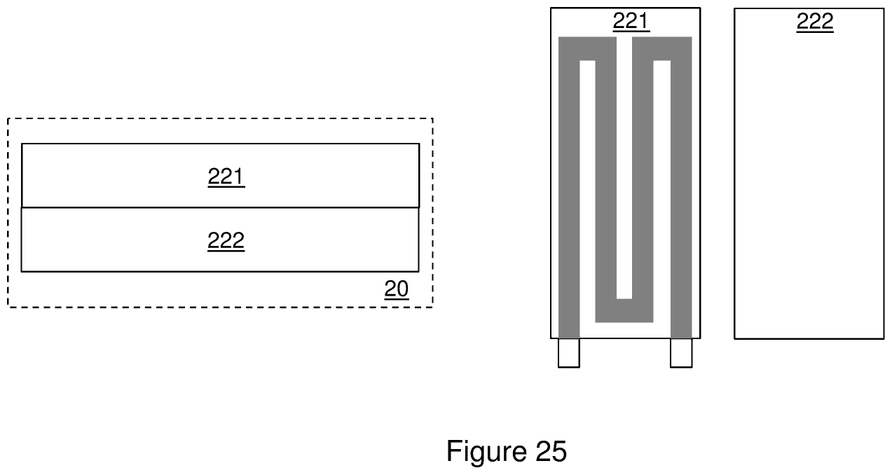

FIG. 25 illustrates a third implementation of the sidewall portion in accordance with various embodiments of the present disclosure. The first sidewall portion 20 is used as an example to illustrate the third implementation. As shown in FIG. 25, the first sidewall portion 20 comprises a first layer 221 and a second layer 222. As shown in FIG. 25, the first layer 221 is in direct contact with the second layer 222. The first layer is formed of copper and functions as an interior sidewall. The first layer comprises a meandering channel extending between an inlet and an outlet. The meandering channel is configured to provide thermal communication with the heat-generating components. The second layer is formed of aluminum and functions as an exterior sidewall.

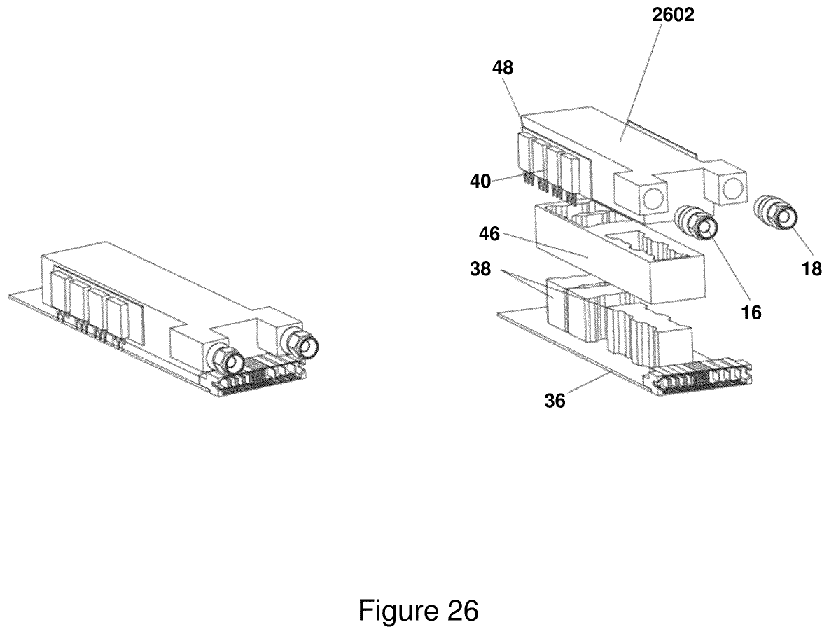

FIG. 26 illustrates an exploded view of the power supply unit comprising a cold plate radiator in accordance with various embodiments of the present disclosure. The power supply unit comprises a cold plate radiator 2602. The left portion of FIG. 26 shows an assembly view, while the right portion shows an exploded view for clarity. As shown in FIG. 26, a PCB 36 supports multiple magnetic components 38 that are thermally coupled to the cold plate radiator 2602 through a thermally-conductive adhesive 46. The thermally-conductive adhesive 46 enhances thermal conduction between the magnetic components 38 and the surface of the cold plate radiator 2602.

The cold plate radiator 2602 includes a liquid inlet 16 and a liquid outlet 18 that form part of a closed loop coolant path. During operation, coolant enters through the inlet 16, circulates within internal liquid channels of the cold plate radiator 2602, and exits through the outlet 18 after absorbing heat transferred from the magnetic components 38. The power switches 40 are mounted on an exterior sidewall of the cold plate radiator 2602. The thermally-conductive interface layer 48 is interposed between the power switches 40 and the cold plate radiator 2602. Under this configuration, the heat generated by the power switches 40 is conducted into the coolant path for dissipation.

In this arrangement, the cold plate radiator 2602 provides a compact and efficient thermal interface for both the magnetic components 38 and the power switches 40. The thermally-conductive adhesive 46 ensures uniform heat transfer from the magnetic components to the radiator surface, while the integrated liquid channels maintain the temperature stability of high-loss components within the power supply unit.

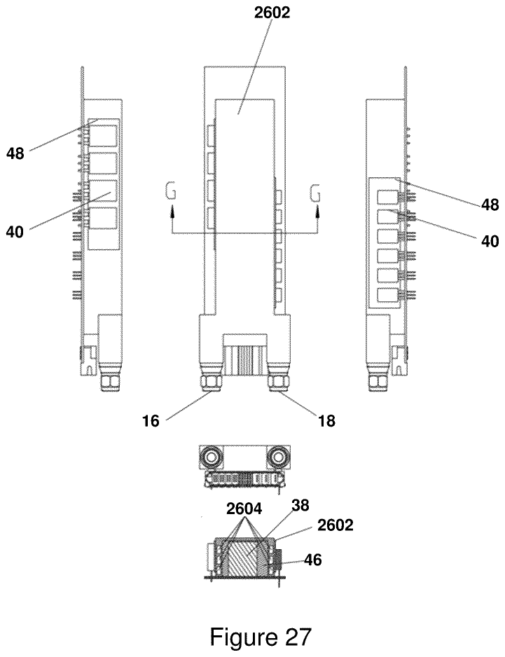

FIG. 27 illustrates a top view and side views of the power supply unit comprising a cold plate radiator in accordance with various embodiments of the present disclosure. FIG. 27 illustrates additional details of the cold plate radiator 2602 shown in FIG. 26. For clarity, the top surface and two sidewalls of the radiator 2602 are laid out on a common plane. This flattened representation allows the arrangement of the power switches 40 and the associated thermal interface components to be more clearly illustrated.

As shown in FIG. 27, the power switches 40 are mounted on both sidewalls of the cold plate radiator 2602. The thermally-conductive interface layer 48 is interposed between each power switch 40 and the corresponding sidewall of the radiator 2602 to improve heat transfer and ensure electrical isolation.

The lower portion of FIG. 27 provides a cross-sectional view along line G-G. The cross section illustrates internal liquid channels 2604 formed within the body of the cold plate radiator 2602. During operation, coolant flows through the liquid channels 2604 to absorb and remove heat from the power switches 40 mounted on both sidewalls and from the magnetic components thermally coupled to the top surface of the cold plate radiator 2602.

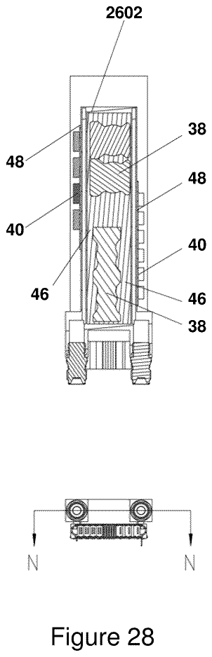

FIG. 28 illustrates a sectional view along a plane that is parallel to the housing floor and that bisects the housing inlet and the housing outlet. As shown in FIG. 28, the sectional view is taken along line N-N.

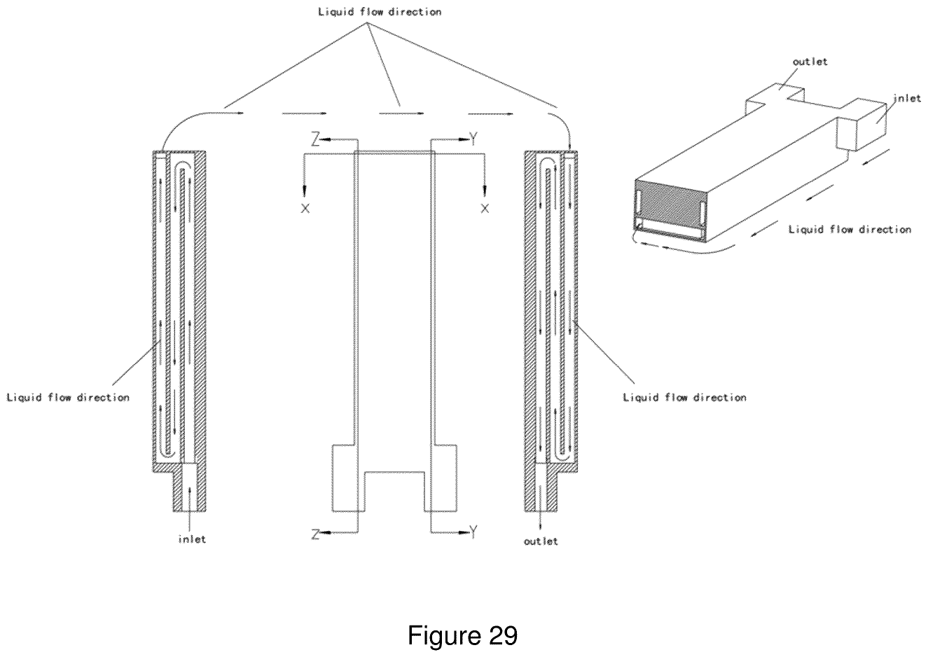

FIG. 29 illustrates a detailed drawing of the cold plate radiator in accordance with various embodiments of the present disclosure. For clarity, the top surface and two sidewalls of the radiator 2602 are laid out on a common plane. The left portion of FIG. 29 shows a cross-sectional view of the left sidewall taken along the line Z-Z. The right portion of FIG. 29 shows a cross-sectional view of the right sidewall taken along the line Y-Y. As shown in FIG. 29, both sidewalls comprise a liquid channel. Coolant enters the liquid channel of the left sidewall from the liquid inlet. The outlet of the liquid channel of the left sidewall is connected to an inlet of the liquid channel of the right sidewall. The coolant flows through the liquid channel of the right sidewall and exits at the liquid outlet.

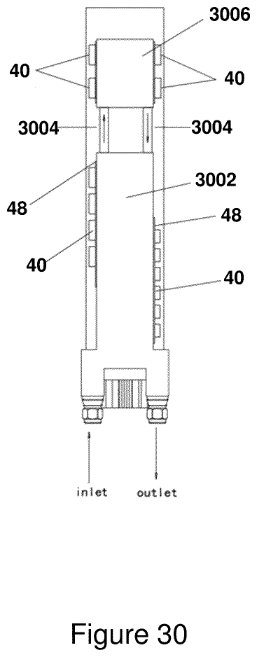

FIG. 30 illustrates a cold plate radiator having a plurality of sub-divisions in accordance with various embodiments of the present disclosure. As shown in FIG. 30, the radiator includes a first sub-division 3002 and a second sub-division 3006, which are fluidly and mechanically connected by a connecting component 3004.

Power switches 40 are mounted on both sidewalls of the sub-divisions 3002 and 3006 so that heat from the switches is transferred into the respective radiator bodies. The connecting component 3004 couples the sub-divisions 3002 and 3006 while maintaining the coolant path between them.

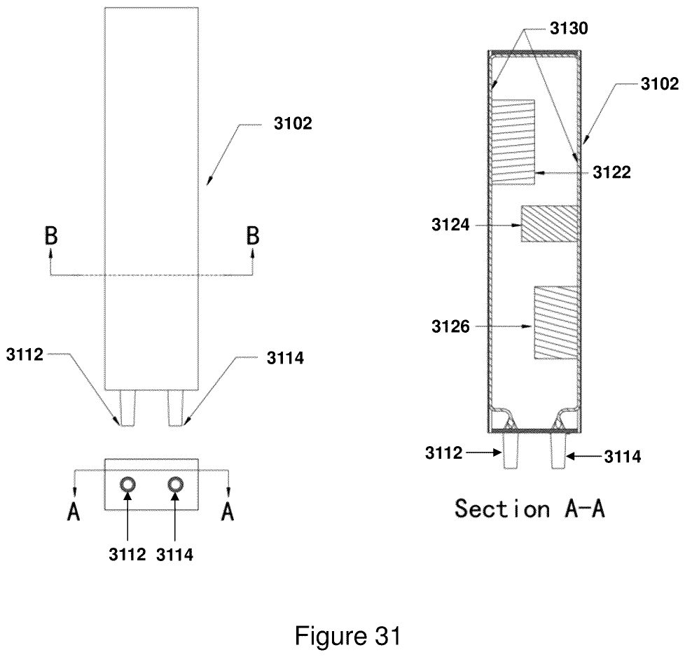

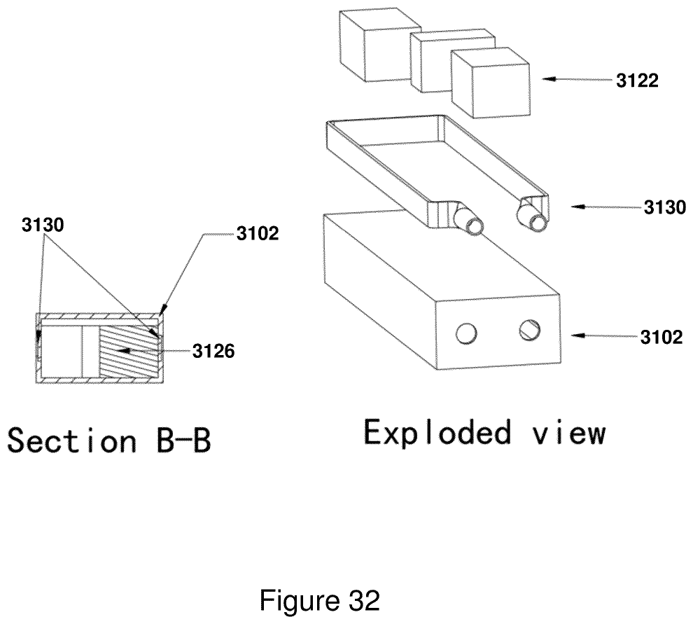

FIGS. 31 and 32 illustrate a first implementation of a liquid-cooled power supply unit in accordance with various embodiments of the present disclosure. FIG. 31 illustrates a cross-sectional view along line A-A of the first implementation. FIG. 32 illustrates an exploded view of the liquid-cooled power supply unit and a cross-sectional view along line B-B of the first implementation.

As shown in FIG. 31, a case 3102 of the power supply unit defines a wall in which a liquid pipe 3130 is embedded to form a liquid-cooled strip for removing heat from internal components. The liquid pipe is connected between an inlet 3112 and an outlet 3114. The inlet 3112, the liquid pipe 3130 and the outlet 3114 allow cooling liquid to circulate through the embedded passage.

Multiple heat-generating components are positioned in thermal contact with the case 3102 so that heat is transferred efficiently to the liquid-cooled strip. These heat-generating components may include a first heat-generating component 3122, a second heat-generating component 3124, and a third heat-generating component 3126. Each of these may represent semiconductor power switches, magnetic components such as transformers or inductors, or other high-loss devices within the power supply unit. Heat generated by these components is conducted through their mounting interfaces to the casing wall, and dissipated through the circulating coolant in the liquid pipe 3130.

As shown in FIG. 32, the liquid pipe 3130 is arranged along the wall of the case 3102. The liquid pipe 3130 is in direct thermal contact with the major heat-generating components, including the first, second, and third heat-generating components 3122, 3124 and 3126. As shown in FIG. 32, the path of the liquid pipe 3130 is configured such that each of these heat-generating components has direct thermal coupling to the cooled region of the case 3102.

The inlet and outlet of the liquid pipe pass through two openings of the case 3102. The inlet and outlet of the liquid pipe allow a coolant such as water or another dielectric liquid to flow through the embedded channel. Heat from the heat-generating components 3122, 3124, and 3126 is thereby transferred to the circulating coolant, maintaining lower device temperatures and improving reliability of the power supply unit.

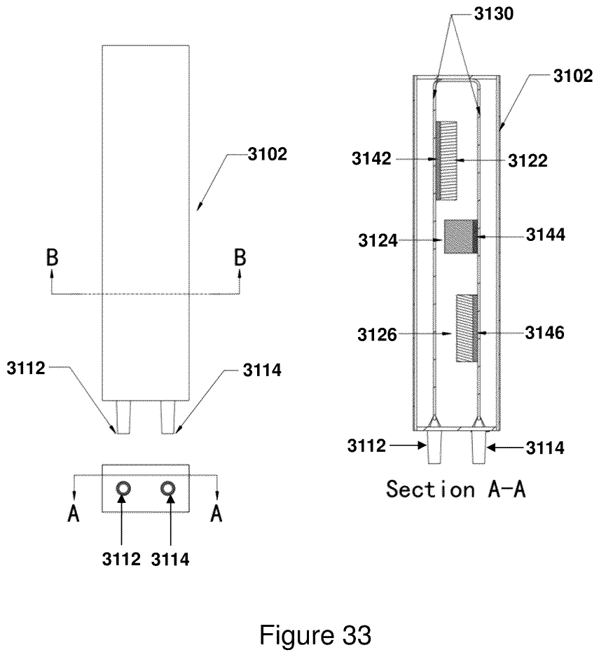

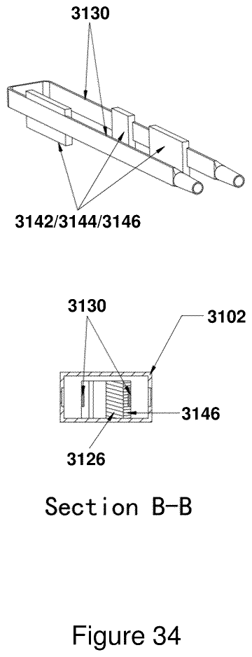

FIGS. 33 and 34 illustrate a second implementation of the liquid-cooled power supply unit in accordance with various embodiments of the present disclosure. FIG. 33 illustrates a cross-sectional view along line A-A of the second implementation. FIG. 34 illustrates a perspective view of the liquid pipe and heatsinks and a cross-sectional view along line B-B of the second implementation.

In FIGS. 33 and 34, the liquid-cooled strip is embedded in a radiator (heatsink) rather than in the wall of the case 3102. In this implementation, heat-generating components transfer heat to the radiator, and the coolant path passes through the radiator.

As shown in FIG. 33, the case 3102 houses multiple heat-generating components, including a first heat-generating component 3122, a second heat-generating component 3124, and a third heat-generating component 3126. The heat-generating components are mounted in thermal contact with one or more radiators (heatsinks) 3142, 3144, and 3146. Portions of the liquid pipe 3130 are embedded in the radiators to form the liquid-cooled strip. The liquid pipe 3130 is connected between an inlet 3112 and an outlet 3114 so that cooling liquid circulates through the interior of the radiators.

As shown in FIG. 34, portions of the liquid pipe 3130 are embedded in the radiators 3142, 3144, and 3146 rather than following the wall of the case 3102. For example, a portion of the liquid pipe 3130 is embedded in the radiator 3142. In some embodiments, a top surface of the liquid pipe 3130 is level with a topmost surface of the radiator 3142 as shown in FIG. 34.

In operation, each radiator is positioned to receive heat from its associated component (e.g., 3122, 3124, or 3126). The coolant flows through the liquid pipe 3130 to remove heat conducted into the radiators 3142, 3144, and 3146.

In this configuration, the primary heat path is from the heat-generating components 3122, 3124 and 3126 into the radiators 3142, 3144 and 3146, and then into the circulating coolant within the liquid pipe 3130, which enters at the inlet 3112 and exits at the outlet 3114.

It should be noted that the number, size, and relative placement of the radiators and the routing of the liquid pipe may be varied as needed while maintaining the coolant path embedded in the radiators.

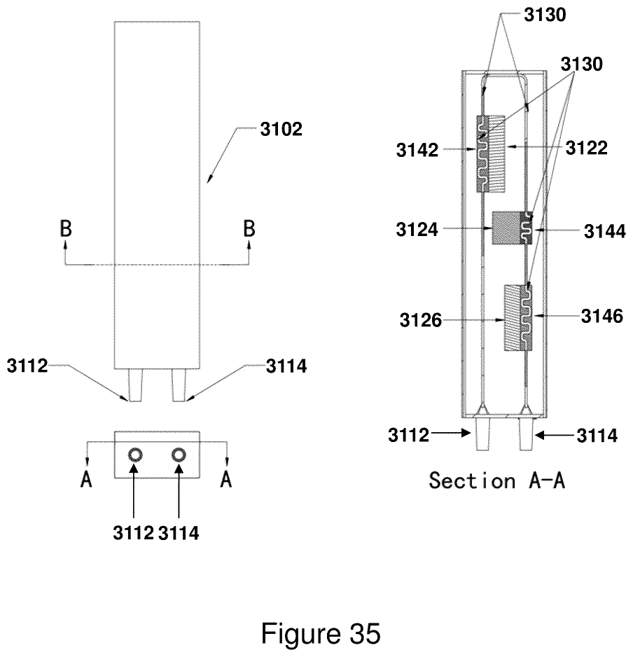

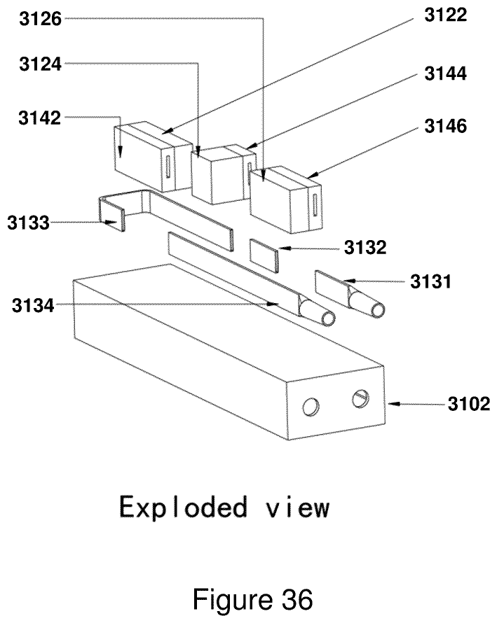

FIGS. 35 and 36 illustrate a third implementation of the liquid-cooled power supply unit in accordance with various embodiments of the present disclosure. FIG. 35 illustrates a cross-sectional view along line A-A of the third implementation. FIG. 36 illustrates an exploded view of the third implementation. In this implementation, the liquid pipe passes through the body of the radiator rather than following the case wall.

As shown in FIG. 35, the case 3102 houses multiple heat-generating components, including a first heat-generating component 3122, a second heat-generating component 3124, and a third heat-generating component 3126. These components are mounted in thermal contact with radiators 3142, 3144 and 3146, respectively. A liquid pipe 3130 is routed through the interior of the radiator body to form the liquid-cooled strip. The liquid pipe is connected between an inlet 3112 and an outlet 3114 to circulate coolant. In the example of FIG. 35, the pipe path within the radiator exhibits a zigzag pattern, which, in some embodiments, may increase the effective contact area between the liquid pipe and the radiator.

As shown in FIG. 36, the liquid pipe 3130 passes through the radiators 3142, 3144, and 3146 to provide internal cooling. The liquid pipe 3130 outside the radiators includes four portions. A first portion 3131 is between the liquid outlet and the radiator 3146. A second portion 3132 is between the radiator 3146 and the radiator 3144. A third portion 3133 is between the radiator 3144 and the radiator 3142. A fourth portion 3134 is between the radiator 3142 and the liquid inlet.

In operation, heat generated by the heat-generating components 3122, 3124, and 3126 is conducted into the radiators 3142, 3144, and 3146 and then into the circulating coolant within the liquid pipe 3130.

It should be noted that the number, size, and placement of the radiators, as well as the internal routing pattern of the liquid pipe, may be varied as needed while preserving coolant flowing through the radiators.

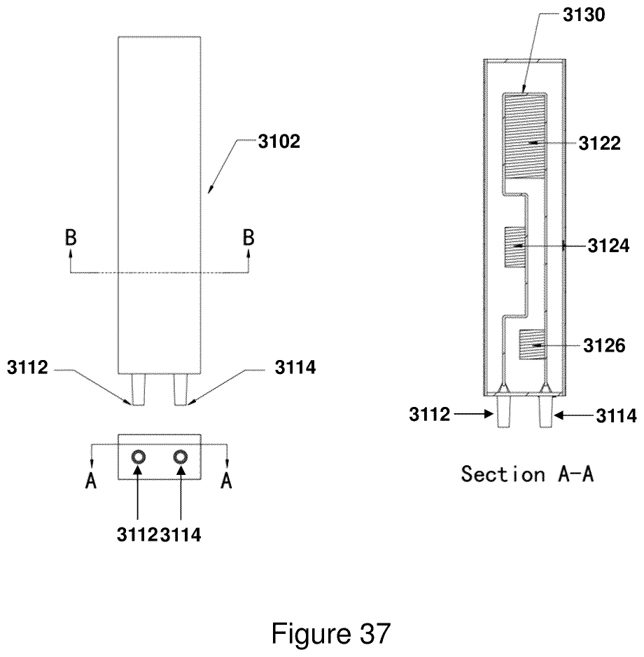

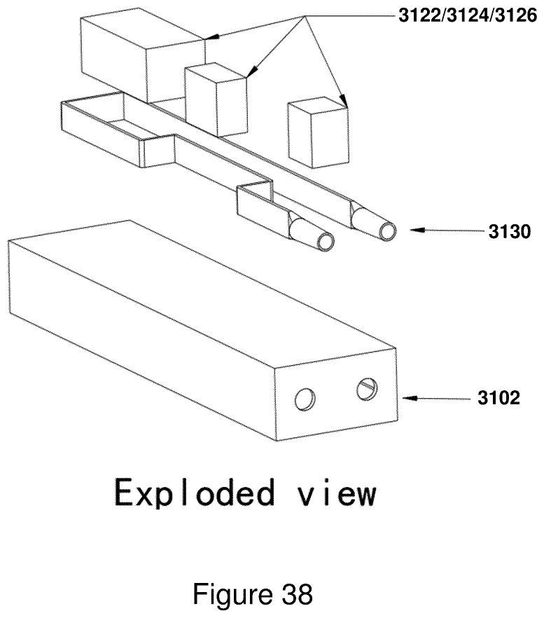

FIGS. 37 and 38 illustrate a fourth implementation of the liquid-cooled power supply unit in accordance with various embodiments of the present disclosure. FIG. 37 illustrates a cross-sectional view along line A-A of the fourth implementation. FIG. 38 illustrates an exploded view of the liquid pipe and heat-generating components of the same implementation.

In FIGS. 37 and 38, the liquid-cooled strip directly contacts the heat-generating components for heat dissipation. The liquid pipe 3130 forms the liquid-cooled strip and is arranged so that its outer surface is in direct thermal contact with the heat-generating components such as the first heat-generating component 3122, the second heat-generating component 3124, and the third heat-generating component 3126.

In this configuration, heat generated by the heat-generating components 3122, 3124, and 3126 is transferred directly to the liquid pipe 3130 without an intermediate radiator structure. The coolant flowing through the liquid pipe 3130 absorbs the heat and carries it away. This direct contact arrangement reduces thermal resistance and improves overall cooling efficiency.

It should be noted that the position, shape, and routing of the liquid pipe 3130, as well as the number and placement of the heat-generating components, may be varied as needed while maintaining direct thermal contact between the liquid pipe and the heat-generating components.

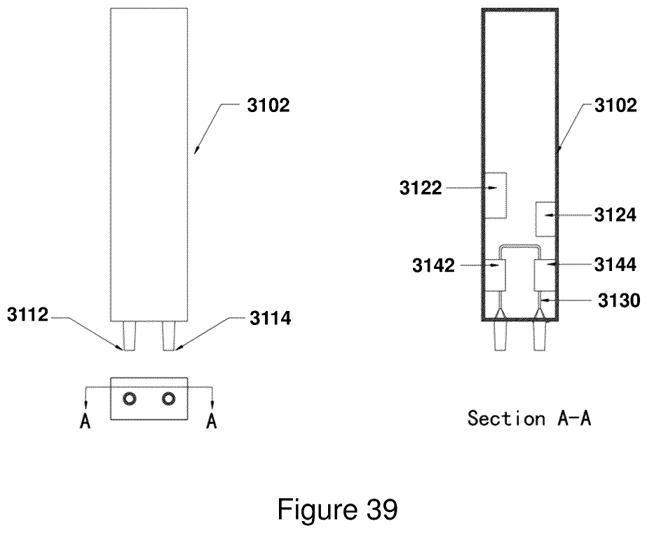

FIG. 39 illustrates a fifth implementation of the liquid-cooled power supply unit in accordance with various embodiments of the present disclosure. In this implementation, the heat-generating components are in thermal contact with the wall of the case, and the liquid-cooled strip is in thermal contact with the case through a radiator (heatsink), thereby achieving cooling of the heat-generating components.

As shown in FIG. 39, the heat-generating components 3122 and 3124 are mounted in direct thermal contact with the wall of the case 3102. Radiators 3142 and 3144 are attached to the wall of the case 3102. The liquid pipe 3130 is thermally coupled to the radiators 3142 and 3144 as shown in FIG. 39. The liquid pipe 3130 is connected between the inlet 3112 and the outlet 3114 so that a coolant can circulate through the radiators 3142 and 3144 to remove heat.

In operation, heat produced by the heat-generating component 3122 and 3124 is conducted through the case 3102 to the radiators 3142 and 3144, and then into the circulating coolant flowing in the liquid pipe 3130. This arrangement provides indirect liquid cooling of the heat-generating components 3122 and 3124 through the combined thermal conduction path of the case and radiators.

It should be noted that the material, thickness, and mounting configuration of the case 3102 and radiators 3142, 3144, as well as the routing of the liquid pipe 3130, may be modified as needed while maintaining the thermal connection between the case and the liquid pipe.

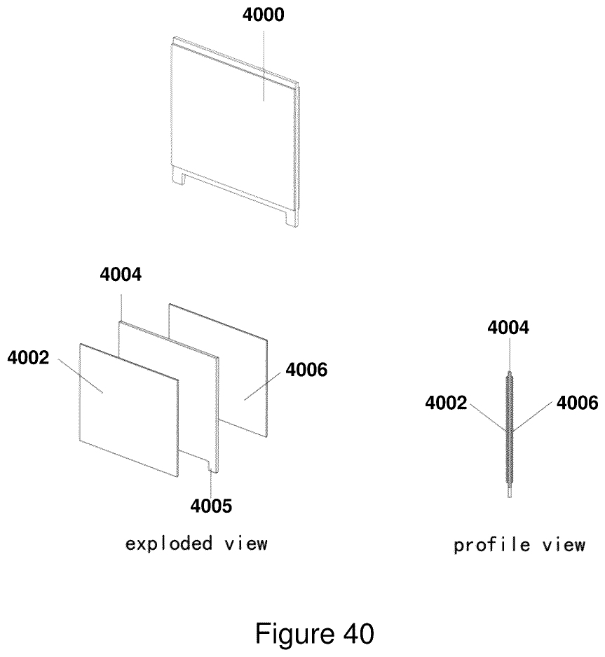

FIG. 40 illustrates a first implementation of a three-layer structure for improving electromagnetic-interference (EMI) performance in the power supply unit in accordance with various embodiments of the present disclosure. In some embodiments, a laminated interface 4000 is placed between the heat-generating component (e.g., 3122) and the radiator 3142 or the case 3102. The laminated interface 4000 includes two outer layers 4002, 4006 and a middle layer 4004. The outer layers 4002 and 4006 are formed of thermally conductive and electrically insulating material. The outer layers provide galvanic isolation while conducting heat from the heat-generating components into the radiator or case. The middle layer 4004 is provided with at least one pin 4005 that can be connected (e.g., by welding or soldering) to a ground plane on a printed circuit board (PCB) to route high frequency noise to ground and thereby improve EMI performance.

The heat-generating components may be secured using fasteners to maintain electrical isolation from the radiator or case. Optional thermal grease or adhesive can be used at the laminated interface 4000 to reduce thermal resistance. In operation, heat flows from the heat-generating components passes through the laminated interface into the radiator or case, while the embedded conductive layer provides a controlled path for high-frequency interference to the ground plane of the PCB.

The insulating layers may be formed from ceramic-filled polymer or other thermally conductive insulating materials and may be bonded to the conductive layer by sintering or coating. The conductive layer may be formed of copper or any suitable conductive materials.

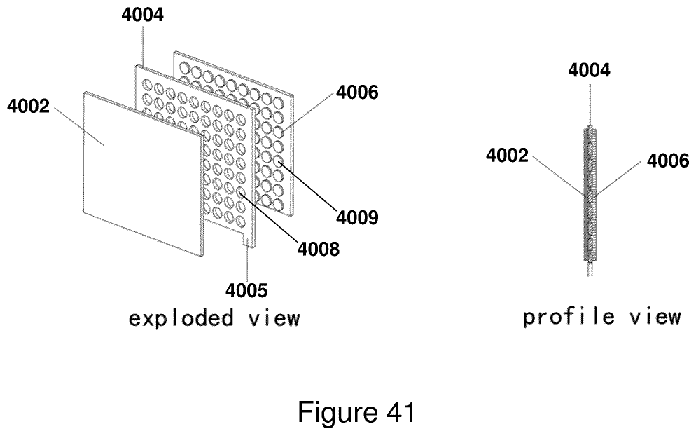

FIG. 41 illustrates a second implementation of the three-layer structure for improving EMI performance in accordance with various embodiments of the present disclosure. FIG. 41 is similar to FIG. 40 except that at least the middle layer 4004 of the laminated interface 4000 is provided with a plurality of mesh holes 4008 to facilitate the sintering or coating processes during fabrication.

The mesh holes 4008 allow improved bonding between the middle conductive layer 4004 and the outer insulating layers 4002 and 4006, thereby enhancing mechanical strength and thermal contact. The mesh holes 4008 also reduce the overall weight of the structure and can help control the electrical impedance of the conductive layer for EMI optimization.

As shown in FIG. 41, in some embodiments, at least one outer layer (e.g., 4006) is provided with a plurality of mesh holes 4009 to facilitate the sintering or coating processes during fabrication.

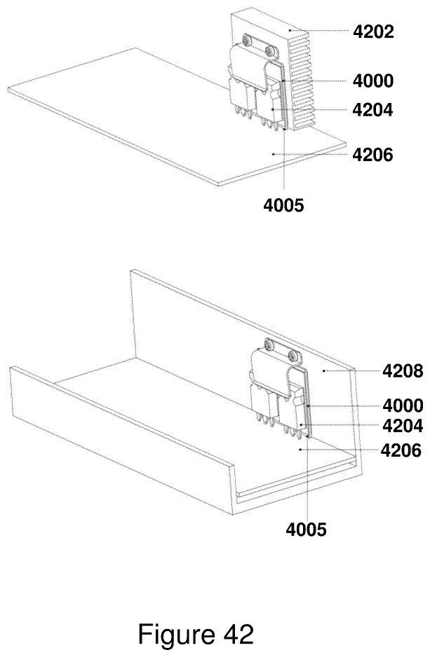

FIG. 42 illustrates an application of the three-layer structure positioned between a heat-generating component and a heatsink in accordance with various embodiments of the present disclosure. As shown in FIG. 42, a Metal-Oxide-Semiconductor Field-Effect Transistor (MOSFET) 4204 is mounted to a heatsink 4202 with the laminated interface 4000 interposed between them. A pin 4005 from the middle conductive layer of the laminated interface 4000 is connected to a ground plane of a PCB 4206.

The laminated interface 4000 provides thermal conduction from the MOSFET 4204 to the heatsink 4202 while maintaining electrical isolation via its outer insulating layers (e.g., 4002 and 4006). The conductive middle layer, via the grounded pin 4005, provides a shielding path that diverts high frequency interference to the ground plane of the PCB 4206, thereby reducing coupling of EMI into the heatsink 4202 or a heat-dissipating case 4208.

In operation, heat produced by the MOSFET 4204 is conducted through the laminated interface 4000 into the heatsink 4202 or the heat-dissipating case 4208. At the same time, the grounded conductive layer of the laminated interface 4000 suppresses common mode or radiated interference by directing EMI currents to the ground plane of the PCB 4206.

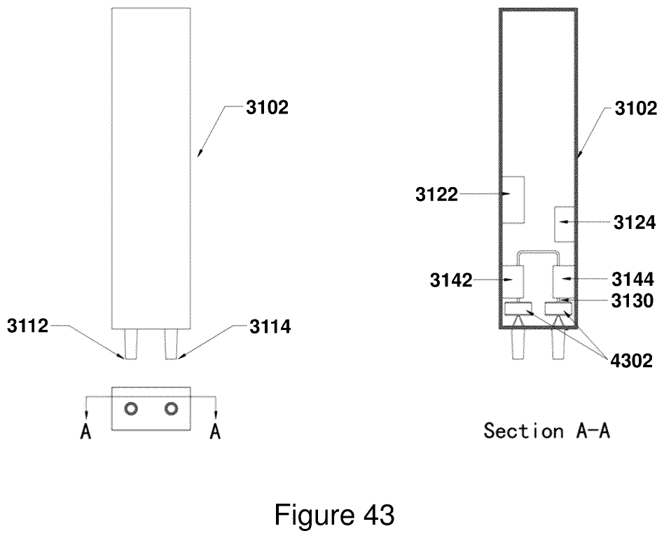

FIG. 43 illustrates a sixth implementation of the liquid-cooled power supply unit in accordance with various embodiments of the present disclosure. The sixth implementation is similar to the implementation shown in FIG. 39 except that additional EMI suppression components are included. In this implementation, magnetic rings 4302 are disposed around a section of the liquid pipe 3130 to provide interference suppression.

As shown in FIG. 43, a first magnetic ring surrounds an exterior segment of the liquid pipe 3130 located between the heatsink 3142 and the pipe inlet. A second magnetic ring surrounds an exterior segment of the liquid pipe 3130 located between the heatsink 3144 and the pipe outlet.

In operation, the magnetic rings increase the impedance to high frequency common mode currents associated with the liquid pipe path and adjacent conductive structures, thereby reducing EMI coupling to the radiators and case.

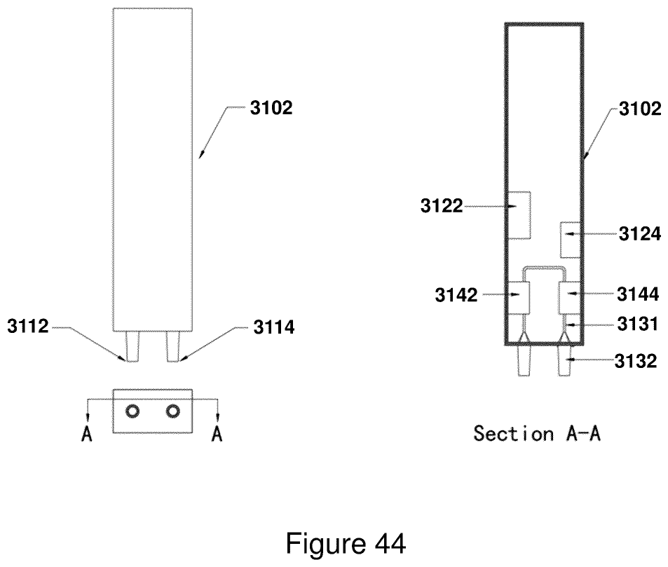

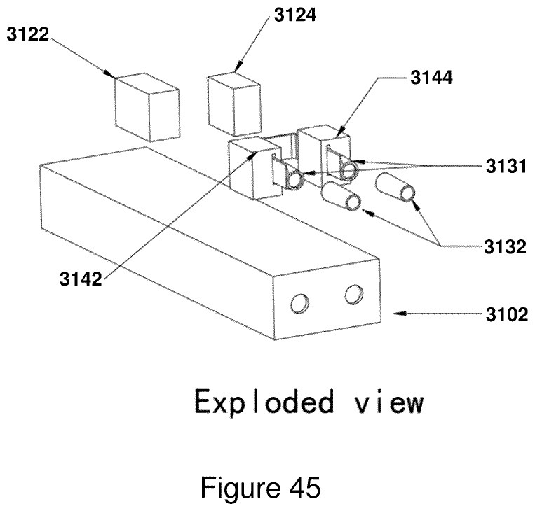

FIGS. 44 and 45 illustrate a seventh implementation of the liquid-cooled power supply unit in accordance with various embodiments of the present disclosure. This implementation is similar to that shown in FIG. 39 except that the liquid pipe outside the case is formed of a plastic material to reduce the likelihood of electromagnetic interference being conducted outward. FIG. 44 illustrates a cross-sectional view along line A-A of the seventh implementation. FIG. 45 illustrates an exploded view of the same implementation.

As shown in FIGS. 44 and 45, the liquid pipe 3130 includes two portions with different materials: a first portion 3131 located inside the case 3102 formed of a metal, and a second portion 3132 located outside the case 3102 formed of a plastic (dielectric) material. The first portion 3131 provides robust thermal conduction within the case, while the second portion 3132 mitigates electromagnetic-interference conduction along the external pipe length.

In some embodiments, the liquid pipe 3130 is connected between an inlet 3112 and an outlet 3114, with at least part of the internal metal portion 3131 thermally coupled to one or more radiators (e.g., 3142, 3144) for heat removal. The external plastic portion 3132 maintains fluid continuity while providing electrical isolation characteristics that reduce common mode coupling to external structures.

It should be noted that the transition between the metal portion 3131 and the plastic portion 3132 may be implemented using a coupler or fitting compatible with the coolant and operating pressures. The material selections, lengths, and routing of the respective portions may be varied as needed while maintaining thermal performance inside the case and interference mitigation outside the case.

It should be understood that the various embodiments described herein may be implemented individually or in any suitable combination. Although certain features, elements, or components are illustrated or described in connection with particular embodiments or figures, such features, elements, or components may be combined or interchanged with those of other embodiments where technically feasible. The omission of a specific combination or modification from the drawings or description should not be construed as an intent to exclude that combination or modification. Those skilled in the art will recognize that numerous variations and substitutions may be made without departing from the spirit and scope of the present disclosure.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A system comprising:
a plurality of power conversion units connected in series between a power source and an output voltage bus; and
a housing comprising a first sidewall portion, a second sidewall portion, a bottom case portion and a top case portion, wherein the plurality of power conversion units is placed inside the housing and at least one of the first sidewall portion, the second sidewall portion, the bottom case portion and the top case portion comprises a channel through which coolant flows to cool heat-generating components of the plurality of power conversion units.

2. The system of claim 1, further comprising:
an inlet and an outlet, wherein the channel extends between the inlet and the outlet, and wherein the channel is configured to provide thermal communication with the heat-generating components; and
a connecting channel, wherein:
the first sidewall portion comprises a first meandering channel connected to the inlet; and
the second sidewall portion comprises a second meandering channel connected to the outlet, and wherein the connecting channel is connected between the first meandering channel and the second meandering channel, and the coolant flows through the first meandering channel, the connecting channel and the second meandering channel and exits through the outlet after absorbing heat generated by the heat-generating components.

3. The system of claim 2, wherein:
the first sidewall portion comprises a first meandering trench, and a first meandering copper tube is embedded in the first meandering trench to form the first meandering channel; and
the second sidewall portion comprises a second meandering trench, and a second meandering copper tube is embedded in the second meandering trench to form the second meandering channel.

4. The system of claim 2, wherein:
the first sidewall portion comprises a first meandering trench;
the second sidewall portion comprises a second meandering trench; and
an integrated copper tube includes a first meandering copper tube portion embedded in the first meandering trench, a second meandering copper tube portion embedded in the second meandering trench and a connecting portion to form the channel.

5. The system of claim 2, wherein:
the top case portion comprises a meandering channel connected between the inlet and the outlet, and wherein the inlet is adjacent to a leftmost corner of the top case portion, and the outlet is adjacent to a rightmost corner of the top case portion.

6. The system of claim 2, wherein:
the bottom case portion comprises a meandering channel connected between the inlet and the outlet, and wherein the inlet is adjacent to a leftmost corner of the bottom case portion, and the outlet is adjacent to a rightmost corner of the bottom case portion.

7. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion, and wherein the first meandering channel is configured to provide thermal communication with the heat-generating components.

8. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion; and
the second sidewall portion comprises a second meandering channel connected between a second inlet and a second outlet, and wherein the second inlet is adjacent to a topmost corner of the second sidewall portion, and the second outlet is adjacent to a bottommost corner of the second sidewall portion, and wherein the first meandering channel and the second meandering channel are configured to provide thermal communication with the heat-generating components.

9. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion; and
the bottom case portion comprises a third meandering channel connected between a third inlet and a third outlet, and wherein the third inlet is adjacent to a leftmost corner of the bottom case portion, and the third outlet is adjacent to a rightmost corner of the bottom case portion, and wherein the first meandering channel and the third meandering channel are configured to provide thermal communication with the heat-generating components.

10. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion; and
the top case portion comprises a fourth meandering channel connected between a fourth inlet and a fourth outlet, and wherein the fourth inlet is adjacent to a leftmost corner of the top case portion, and the fourth outlet is adjacent to a rightmost corner of the top case portion, and wherein the first meandering channel and the fourth meandering channel are configured to provide thermal communication with the heat-generating components.

11. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion;
the second sidewall portion comprises a second meandering channel connected between a second inlet and a second outlet, and wherein the second inlet is adjacent to a topmost corner of the second sidewall portion, and the second outlet is adjacent to a bottommost corner of the second sidewall portion; and
the bottom case portion comprises a third meandering channel connected between a third inlet and a third outlet, and wherein the third inlet is adjacent to a leftmost corner of the bottom case portion, and the third outlet is adjacent to a rightmost corner of the bottom case portion, and wherein the first meandering channel, the second meandering channel and the third meandering channel are configured to provide thermal communication with the heat-generating components.

12. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion;
the second sidewall portion comprises a second meandering channel connected between a second inlet and a second outlet, and wherein the second inlet is adjacent to a topmost corner of the second sidewall portion, and the second outlet is adjacent to a bottommost corner of the second sidewall portion; and
the top case portion comprises a fourth meandering channel connected between a fourth inlet and a fourth outlet, and wherein the fourth inlet is adjacent to a leftmost corner of the top case portion, and the fourth outlet is adjacent to a rightmost corner of the top case portion, and wherein the first meandering channel, the second meandering channel and the fourth meandering channel are configured to provide thermal communication with the heat-generating components.

13. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion;
the bottom case portion comprises a third meandering channel connected between a third inlet and a third outlet, and wherein the third inlet is adjacent to a leftmost corner of the bottom case portion, and the third outlet is adjacent to a rightmost corner of the bottom case portion; and
the top case portion comprises a fourth meandering channel connected between a fourth inlet and a fourth outlet, and wherein the fourth inlet is adjacent to a leftmost corner of the top case portion, and the fourth outlet is adjacent to a rightmost corner of the top case portion, and wherein the first meandering channel, the third meandering channel and the fourth meandering channel are configured to provide thermal communication with the heat-generating components.

14. The system of claim 1, wherein:
the first sidewall portion comprises a first meandering channel connected between a first inlet and a first outlet, and wherein the first inlet is adjacent to a topmost corner of the first sidewall portion, and the first outlet is adjacent to a bottommost corner of the first sidewall portion;
the second sidewall portion comprises a second meandering channel connected between a second inlet and a second outlet, and wherein the second inlet is adjacent to a topmost corner of the second sidewall portion, and the second outlet is adjacent to a bottommost corner of the second sidewall portion;
the bottom case portion comprises a third meandering channel connected between a third inlet and a third outlet, and wherein the third inlet is adjacent to a leftmost corner of the bottom case portion, and the third outlet is adjacent to a rightmost corner of the bottom case portion; and
the top case portion comprises a fourth meandering channel connected between a fourth inlet and a fourth outlet, and wherein the fourth inlet is adjacent to a leftmost corner of the top case portion, and the fourth outlet is adjacent to a rightmost corner of the top case portion, and wherein the first meandering channel, the second meandering channel, the third meandering channel and the fourth meandering channel are configured to provide thermal communication with the heat-generating components.

15. The system of claim 1, wherein the first sidewall portion comprises a first layer, a second layer and a third layer, and wherein:
the first layer is in direct contact with the second layer, and the second layer is in direct contact with the third layer;
the first layer is formed of aluminum and functions as an interior sidewall;
the second layer is formed of copper and comprises a meandering channel extending between an inlet and an outlet, and wherein the meandering channel is configured to provide thermal communication with the heat-generating components; and
the third layer is formed of aluminum and functions as an exterior sidewall.

16. The system of claim 1, wherein the first sidewall portion comprises a first layer and a second layer, and wherein:
the first layer is in direct contact with the second layer;
the first layer is formed of aluminum and functions as an interior sidewall; and
the second layer is formed of copper and functions as an exterior sidewall, and wherein the second layer comprises a meandering channel extending between an inlet and an outlet, and wherein the meandering channel is configured to provide thermal communication with the heat-generating components.

17. The system of claim 1, wherein the first sidewall portion comprises a first layer and a second layer, and wherein:
the first layer is in direct contact with the second layer;
the first layer is formed of copper and functions as an interior sidewall, and wherein the first layer comprises a meandering channel extending between an inlet and an outlet, and wherein the meandering channel is configured to provide thermal communication with the heat-generating components; and
the second layer is formed of aluminum and functions as an exterior sidewall.

18. A power supply unit comprising:
a printed circuit board on which one or more magnetic components are mounted;
a cold plate radiator having at least one liquid channel, the cold plate radiator including a liquid inlet and a liquid outlet configured to allow coolant circulation;
a thermally conductive adhesive disposed between the magnetic components and the cold plate radiator; and
a plurality of power switches thermally coupled to sidewalls of the cold plate radiator, wherein the coolant flowing through the liquid channel absorbs heat generated by the magnetic components and the power switches.

19. The power supply unit of claim 18, wherein:
the cold plate radiator comprises a plurality of sub-divided radiator bodies connected by a coupling component that maintains fluid communication between the sub-divided radiator bodies.

20. The power supply unit of claim 18, wherein:
the liquid channel comprises a meandering flow path that extends through two sidewalls of the cold plate radiator.

21. The power supply unit of claim 18, wherein:
the coolant enters the liquid channel through the liquid inlet, flows through a first sidewall, passes to a second sidewall through an internal connection passage, and exits the liquid outlet.

22. A liquid-cooled power supply unit comprising:
a case having a wall;
a liquid pipe disposed inside the case and arranged along the wall or in thermal contact with a radiator; and
a plurality of heat-generating components thermally coupled to the liquid pipe through the wall or through at least one radiator, wherein a coolant flows through the liquid pipe to remove heat from the plurality of heat-generating components.

23. The liquid-cooled power supply unit of claim 22, wherein:
the liquid pipe is positioned inside the case and routed to sequentially pass regions adjacent to the plurality of heat-generating components to improve cooling uniformity.

24. The liquid-cooled power supply unit of claim 22, wherein:
at least a portion of the liquid pipe passes through the radiator.

25. The liquid-cooled power supply unit of claim 22, wherein:
a section of the liquid pipe located outside the case is formed of a plastic material, and a section of the liquid pipe located inside the case is formed of a metal material.

26. The liquid-cooled power supply unit of claim 22, further comprising:
one or more electromagnetic-interference suppression components positioned along the liquid pipe and/or between the heat-generating components and the radiator.
